(19) United States
(12) Patent Application Publication
(10) Pub. No.: US 2026/0179668 A1
(43) Pub. Date: Jun. 25, 2026

(54) MEMORY CELL ARRANGEMENT AND METHODS FOR OPERATING A MEMORY CELL ARRANGEMENT

(71) Applicant: Ferroelectric Memory GmbH, Dresden (DE)

(72) Inventors: Johannes Ocker, Dresden (DE); Corrado Villa, Sovico (IT)

(21) Appl. No.: 18/987,064

(22) Filed: Dec. 19, 2024

(51) Int. Cl. G11C 11/22

(52) U.S. Cl. CPC G11C 11/2273; G11C 11/2275; G11C 11/2293

(57) ABSTRACT

Various aspects relate to a memory cell arrangement including: a plurality of memory cells, wherein each memory cell of the plurality of memory cells includes a respective remanent-polarizable memory layer; and a controller configured to cause a conditioning operation for each memory cell of a first subset of memory cells of the plurality of memory cells, the conditioning operation including for a respective memory cell of the first subset of memory cells: reading a memory state of the respective memory cell and writing an assigned memory cell of a second subset of memory cells of the plurality of memory cells into the memory state, the second subset of memory cells being different from the first subset of memory cells; and, subsequently, causing an alternating sequence of voltage drops of opposite polarities over the respective remanent-polarizable memory layer of the respective memory cell.

### TECHNICAL FIELD

Various aspects relate to a memory cell arrangement and methods for operating a memory cell arrangement (e.g., when powering up the memory cell arrangement and/or during operation of the memory cell arrangement).

### BACKGROUND

In general, various computer memory technologies have been developed in semiconductor industry. A fundamental building block of a computer memory may be referred to as memory cell. The memory cell may be an electronic circuit that is configured to store at an information (e.g., bitwise). As an example, the memory cell may have at least two memory states representing, for example, a logic “1” and a logic “0”. In general, the information may be maintained (stored) in a memory cell until the memory state of the memory cell is modified, e.g., in a controlled manner. The information stored in the memory cell may be obtained (read out) by determining in which of the memory states the memory cell is residing in. At present, various types of memory cells may be used to store data. By way of example, a remanent-polarizable memory cell may include a thin film of a spontaneous-polarizable material, e.g., a ferroelectric material or a configuration of an anti-ferroelectric material, whose polarization state may be changed in a controlled fashion to store data in the memory cell, e.g., in a non-volatile, remanent manner. Such a remanent-polarizable memory cell may exhibit an imprint effect according to which a memory state the remanent-polarizable memory cell is in becomes more stable the longer the remanent-polarizable memory cell is in the same memory state. After some time period, it may not even be possible to write the remanent-polarizable memory cell into an opposite memory state any more.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects of the invention are described with reference to the following drawings, in which:

FIG. 1 shows an exemplary memory cell arrangement including a plurality of memory cells and various control lines for addressing the plurality of memory cells;

FIG. 2 shows an equivalent circuit of a memory cell that, during a read-out operation, is provided with a read voltage to develop a characteristic voltage at the bitline according to various aspects;

FIG. 3 shows an example of a typical hysteresis curve of a remanent-polarizable memory structure that plots the polarization as a function of the voltage across it;

FIG. 4 shows a typical timing diagram of a read-out operation for determining a memory state of a memory cell;

FIG. 5 shows an exemplary configuration of a sense amplifier according to various aspects;

FIG. 6 shows various aspects of electrical polarization and imprint characteristics of a remanent-polarizable memory cell;

FIG. 7 shows various aspects of reading an imprinted memory state according to various aspects;

FIG. 8 shows various aspects of a temporal behavior of the imprint characteristics with and without using the inversion operation detailed herein according to various aspects;

FIG. 9 shows various aspects of reducing the imprint by applying an alternating sequence of voltage drops of opposite polarities over the remanent-polarizable memory cell; and

FIG. 10 and FIG. 11 each show a flow diagram of a method for operating a memory cell arrangement according to various aspects.

### DESCRIPTION

The following detailed description refers to the accompanying drawings that show, by way of illustration, specific details and aspects in which the invention may be practiced. These aspects are described in sufficient detail to enable those skilled in the art to practice the invention. Other aspects may be utilized and structural, logical, and electrical changes may be made without departing from the scope of the invention. The various aspects are not necessarily mutually exclusive, as some aspects may be combined with one or more other aspects to form new aspects. Various aspects are described in connection with methods and various aspects are described in connection with devices (e.g., a memory cell, or a memory capacitor). However, it may be understood that aspects described in connection with methods may similarly apply to the devices, and vice versa.

In general, a memory state of a selected (state-programmable) capacitive, remanent-polarizable memory cell may be read by applying a plateline voltage V_{PL} at a plateline connected to the memory cell and by applying a wordline voltage V_{WL} at a wordline connected to the memory cell (to open its access device) to thereby charge a bitline connected to the memory cell to a characteristic voltage that depends on the memory state of the memory cell.

To write the memory cell into a memory state, a write voltage may be applied at the bitline and about 0 V may be applied at the plateline (e.g., to write a logic “1”), or vice versa (e.g., to write a logic “0”).

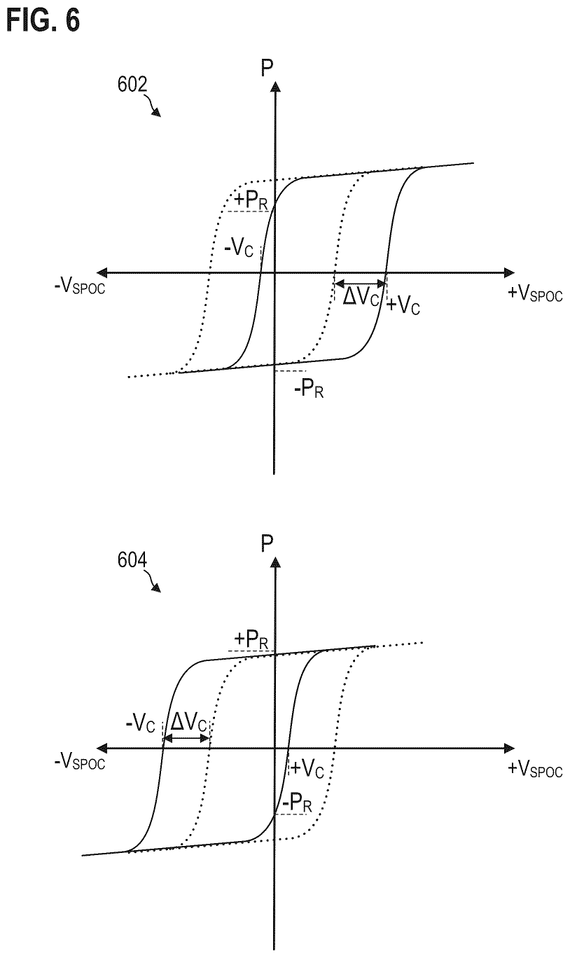

A remanent-polarizable memory cell may exhibit an imprint effect which (energetically) stabilizes the memory state the remanent-polarizable memory cell is in over time. Thus, the longer the remanent-polarizable memory cell is in a same memory state, the more stable this memory state becomes. This may result in that a higher read voltage (viz. plateline voltage V_{PL}) has to be applied. However, after some time the imprint may be that strong that the memory cell cannot be written to its opposite state (e.g., to logic “0” in the case that the imprinted memory state is logic “1”, or vice versa), as described herein in further detail (e.g., with reference to FIG. 6). It is understood that even ECC cannot completely prevent data loss in such a scenario.

Various aspects detailed herein relate to reducing (e.g., preventing) this imprint effect. It is understood that the imprint effect serves as an example and that the aspects detailed herein allow to reduce any effect that causes a modification (e.g., shift) of the memory window of a remanent-polarizable memory cell. Hence, various relate to a memory cell arrangement and an operation thereof that allows a reduction of imprint of a memory cell (or a comparable effect that may cause a modification (e.g., shift) of a memory window of the memory cell).

Various aspects relate to a memory cell arrangement including: a plurality of memory cells, wherein each memory cell of the plurality of memory cells includes a respective remanent-polarizable memory layer; and a controller configured to cause a conditioning operation for each memory cell of a first subset of memory cells of the plurality of memory cells, the conditioning operation including for a respective memory cell of the first subset of memory cells: reading a memory state of the respective memory cell and writing an assigned memory cell of a second subset of memory cells of the plurality of memory cells into the memory state, the second subset of memory cells being different from the first subset of memory cells; and, subsequently, causing an alternating sequence of voltage drops of opposite polarities over the respective remanent-polarizable memory layer of the respective memory cell.

A memory cell arrangement is usually configured in a matrix-type arrangement, wherein columns and rows define the addressing of the memory cells according to the control lines connecting respectively subsets of memory cells of the memory cell arrangement along the rows and columns of the matrix-type arrangement. However, other arrangements may be suitable as well. In general, a memory cell arrangement may include a plurality of (e.g., volatile or non-volatile) memory cells, which may be accessed individually or on groups via a corresponding addressing scheme. The matrix architecture may be, for example, referred to as “OR”, “AND”, “NOR”, or “NAND” architecture, depending on the way neighboring memory cells are connected to each other, i.e., depending on the way the terminals of neighboring memory cells are shared, but are not limited to these two types (another type is for example an “AND” architecture). For example, in a NAND architecture the memory cells may be organized in sectors (also referred to as blocks) of memory cells, wherein the memory cells are serially connected in a string (e.g., source and drain regions are shared by neighboring transistors), and the string is connected to a first control line and a second control line. For example, groups of memory cells in a NAND architecture may be connected in series with one another. In a NOR architecture the memory cells may be connected in parallel with one another. A NAND architecture may thus be more suited for serial access to data stored in the memory cells, whereas a NOR architecture may be more suited for random access to data stored in the memory cells.

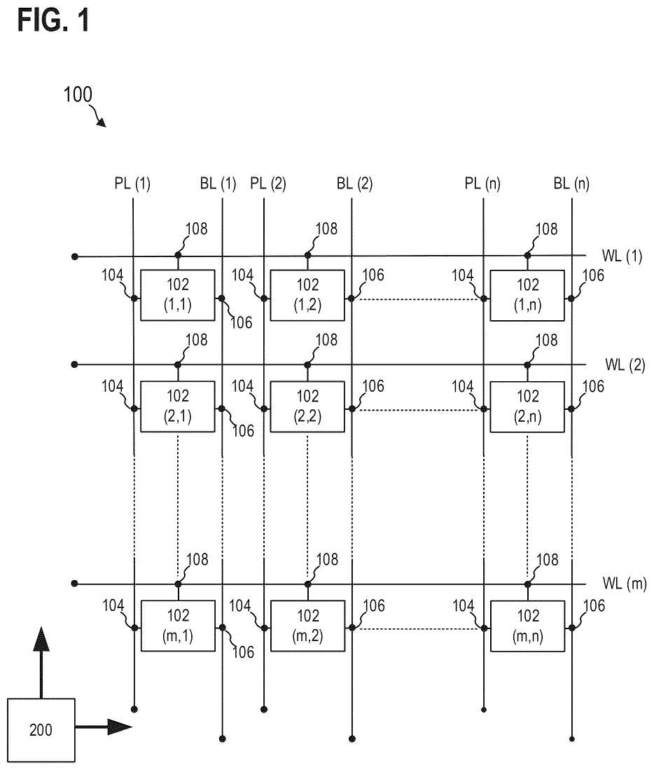

FIG. 1 shows an exemplary memory cell arrangement 100 including a plurality of memory cells 102(m=1 to M, n=1 to N). In the following, various aspects are detailed with reference to the memory cell arrangement 100. It is understood that the memory cell arrangement 100 serves as an exemplary memory cell arrangement to illustrate those aspects and that the memory cell arrangement may have any other suitable configuration.

The plurality of memory cells 102(m=1 to M, n=1 to N) may be arranged an array of N times M. “N” may be any integer number equal to or greater than one. “M” may be any integer number equal to or greater than one. In some aspects, the memory cell arrangement 100 may be in a ferroelectric random-access memory (FeRAM) configuration.

The memory cell arrangement 100 may include a plurality of bitlines BL(n=1 to N), a plurality of platelines PL(n=1 to N), and a plurality of wordlines WL(m=1 to M) for (individually and selectively) addressing the plurality of memory cells 102(m=1 to M, n=1 to N). Each memory cell 102(m*, n*) may be connected to and selectively (and individually) addressable via a corresponding bitline BL(n*) of the plurality of bitlines BL(n=1 to N), a corresponding wordline WL(m*) of the plurality of wordlines WL(m=1 to M), and a corresponding plateline PL(n*) of the plurality of platelines PL(n=1 to N). The *-notation may define one specific integer for the corresponding variable, such as a specific n* for the variable n, a specific m* for the variable m, etc.

In this exemplary configuration, each memory cell 102(m*, n*) may be a three-terminal memory cell having a first terminal 104, a second terminal 106, and a third terminal 108. The first terminal 104 of a respective memory cell 102(m*, n*) may be coupled to the corresponding plateline PL(n*). The second terminal 106 of the respective memory cell 102(m*, n*) may be coupled to the corresponding bitline BL(n*). The third terminal 108 of the respective memory cell 102(m*, n*) may be coupled to the corresponding wordline WL(m*).

The memory cell arrangement 100 may include a controller 200 (in some aspects referred to as control circuit). The controller 200 may be configured to apply a respective voltage to each control line described herein. The control controller 200 may be configured to apply a plateline voltage, V_{PL}, (via the corresponding plateline PL(n*)) at the first terminal 104, a bitline voltage, V_{BL}, (via the corresponding bitline BL(n*)) at the second terminal 106, and a wordline voltage, V_{WL}, (via the corresponding wordline WL(m*)) at the third terminal 108 of the memory cell 102(m*, n*) in order to address the memory cell 102(m*, n*). The controller 200 may be configured to cause (viz. initiate) (e.g., to carry out) a write operation to write a memory state of at least one memory cell 102(m*, n*). The controller 200 (e.g., including a read-out circuit) may be configured to cause (viz. initiate) (e.g., carry out) a read-out operation (short: read operation) to read out the memory state of the at least one memory cell 102(m*, n*).

“Writing” a memory cell, as used herein, may be understood as bringing the memory cell into one of at least two different memory states. Writing a memory cell may also be referred to as programming the memory cell, wherein the memory state the memory cell is residing in after programming may be called “programmed state”. Therefore, the memory cell may also be referred to as state-programmable memory cell.

“Reading” a memory cell, as used herein, may be understood as determining the memory state the memory cell is residing in (e.g., programmed to). In general, a memory cell may be read either non-destructively (if the read-out operation does not change the memory state the memory cell is residing in) or destructively (if the read-out operation changes the memory state the memory cell is residing in). Thus, a destructive read-out operation may require a write operation subsequent to read-out in order to program again the memory state of the memory cell.

Various aspects detailed herein with reference to the controller 200 may be implemented by one or more components. For example, one or more than one state machine may be configured to carry out some operations of the controller 200 and one or more than one memory controller may be configured to carry out other operations of the controller 200. However, there may also be operations that can be carried out by a state machine and a memory controller and/or by their interaction.

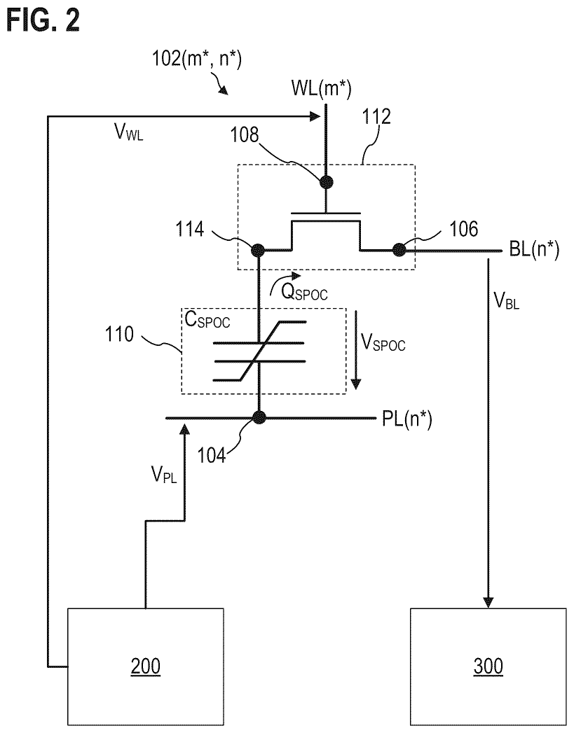

FIG. 2 shows an equivalent circuit of the memory cell 102(m*, n*) according to various aspects. As detailed herein, the memory cell arrangement 100 serves as an exemplary memory cell arrangement; thus, the memory cell 102(m*, n*) described herein may also be part of any other memory cell arrangement configured differently.

The memory cell 102(m*, n*) may include the first terminal 104 coupled to the corresponding plateline PL(n*), the second terminal 106 coupled to the corresponding bitline BL(n*), and the third terminal 108 coupled to the corresponding wordline WL(m*).

The memory cell 102(m*, n*) may include a capacitive memory structure, such as a spontaneously polarizable capacitor, SPOC, structure 110. Therefore, the memory cell 102(m*, n*) may be referred to as capacitive memory cell or capacitor-type memory cell. The SPOC structure 110 may include a memory element disposed between at least two electrodes (e.g., two electrode layers).

As detailed herein, the SPOC structure 110 may be writable into at least two (different) remanent polarizable memory states. Hence, the memory cell 102(m*, n*) may be a remanent-polarizable memory cell.

The memory cell 102(m*, n*) may include an access device. Herein, for illustration, the access device is described exemplarily as a field effect transistor (FET), such as a field-effect transistor (FET) structure 112 providing the (e.g., n-type or p-type) FET. It is understood that this serves for illustration and that the access device may be any other kind of access device.

The field-effect transistor, FET, structure 112 may include a gate structure, wherein the gate structure may include a gate isolation and a gate electrode. The gate structure may be a planar gate stack or may have another field-effect transistor designs with a non-planar shape, for example a trench gate transistor design, a vertical field-effect transistor design, or other designs, such as a fin-FET design. The gate electrode may be connected to the third terminal 108. Therefore, the third terminal 108 may also be referred to as gate terminal. The FET structure 112 may include a first source/drain terminal and a second source/drain terminal. The second source/drain terminal may be connected to the second terminal 106 of the memory cell 102(m*, n*). A first electrode of the SPOC structure 110 may be coupled to the first terminal 104 and a second electrode of the SPOC structure 110 may be connected to the first source/drain terminal of the FET structure 112. The node coupled between the FET structure 112 and the SPOC structure 110 may be referred to as storage node (SN) 114 or storage terminal.

As detailed herein, the exemplarily described memory cell 102(m*, n*) may include at least one capacitor (the SPOC structure 110) and a transistor (the FET structure 112) such that the memory cell 102(m*, n*) may be a one transistor, T, one capacitor, C, memory cell (1T1C cell). It is understood that this serves for illustration and that the memory cell 102(m*, n*) may include more than one capacitor, thus being a one transistor multiple capacitors memory cell (1TxC cell). Further, it is understood that this three-terminal 1T1C memory cell serves as an example to illustrate various aspects of reducing imprint of memory cells and that the memory cell may also be a two-terminal memory cell including the one capacitor, C, coupled between the two terminals. In this case, the memory cell arrangement may include an access transistor coupled to a same control line of a plurality of two-terminal memory cells.

The memory state of the memory cell may be associated with a (remanent) polarization state of the SPOC structure 110 (e.g., its memory element). The (remanent) polarization state of the SPOC 110 may determine the amount of charge stored therein. The amount of charge stored in the SPOC structure 110 may be used to define the memory state of the memory cell. Thus, writing the memory cell may be associated with applying an electric field over the SPOC structure 110 to thereby set (e.g., change) the (e.g., remanent) polarization state of the SPOC structure 110.

The memory element may include or may consist of a spontaneously polarizable material. For example, the spontaneously polarizable material may be a remanent polarizable material, such as a ferroelectric material, or a non-remanent polarizable material, such as an anti-ferroelectric material. A memory element including or consisting of a spontaneously polarizable material may be understood such that the memory element has (e.g., within the framework of the SPOC structure 110) spontaneously polarizable properties. The SPOC structure 110 may provide a spontaneously polarizable capacitor (in some aspects also referred to as memory capacitor).

The spontaneously-polarizable memory element may show a hysteresis in the (voltage (drop) dependent) polarization. The spontaneously-polarizable memory element may show non-remanent spontaneous polarization (e.g., may show anti-ferroelectric properties), e.g., the spontaneously-polarizable memory element may have no or no substantial remanent polarization remaining in the case that no voltage drops over the spontaneously-polarizable memory element. In other aspects, the spontaneously-polarizable memory element may show remanent spontaneous polarization (e.g., may show ferroelectric properties), e.g., the spontaneously-polarizable memory element may have a remanent polarization or a substantial remanent polarization remaining in the case that no voltage drops over the spontaneously-polarizable memory element.

The terms “spontaneously polarized” or “spontaneous polarization” may be used herein, for example, with reference to the polarization capability of a material beyond dielectric polarization. A “spontaneously-polarizable” (or “spontaneous-polarizable”) material may be or may include a spontaneously-polarizable material that shows a remanence, e.g., a ferroelectric material, and/or a spontaneously-polarizable material that shows no remanence, e.g., an anti-ferroelectric material. The coercivity of the spontaneously-polarizable material may be a measure of the strength of the reverse polarizing electric field that may be required to remove a remanent polarization.

A spontaneous polarization (e.g., a remanent or non-remanent spontaneous polarization) may be evaluated via analyzing one or more hysteresis measurements (e.g., hysteresis curves), e.g., in a plot of polarization, P, versus electric field, E, in which the material is polarized into opposite directions. The polarization capability of a material (dielectric polarization, spontaneous polarization, and a remanence characteristics of the polarization) may be analyzed using capacity spectroscopy, e.g., via a static (C-V) and/or time-resolved measurement or by polarization-voltage (P-V) or positive-up-negative-down (PUND) measurements. Another method for determining a polarization capability of a state-programmable memory element may include transmission electron microscopy, e.g., an electric-field dependent transmission electron microscopy.

The memory state may be understood as referring to a remanent polarization state that is set by applying a particular voltage across the SPOC structure 110 that is sufficient to set a corresponding polarization state, where, once set, the remanent polarization state is retained by the SPOC structure 110 even when the voltage across the SPOC structure 110 has been removed (e.g., it is remanently-polarizable). Once such a capacitive structure has been state-programmed to a remanent state, it generally retains the programmed state until it is re-programmed by applying a voltage across it that is sufficient to program the element to a (e.g., new) remanent state. As detailed herein, in a usual capacitive memory cell, the amount of charge stored in the capacitor structure may be used to define a memory state (e.g., a first amount of charge stored in the capacitor structure may define a first memory state and a second amount of charge stored in the capacitor structure and different from the first amount of charge may define a second memory state). As used herein, a (memory) state of a memory cell is described as “remanent” where the SPOC structure 110 is capable of retaining its programmed state even when it is not connected to a power source. As also used throughout, the current remanent state to which the memory element has been set may be referred to as the “stored” state, the “written” state, or the “programmed” state.

According to various aspects, in various types of applications, e.g., in memory technology, a remanent polarization as low as 0 μC/cm² to 3 μC/cm² may be regarded as no substantial remanent polarization. Such low values of a remanent polarization may be present in a layer or material due to undesired effects, e.g., due to a not ideal layer formation. According to various aspects, in various types of applications, e.g., in memory technology, a remanent polarization greater than 3 μC/cm² may be regarded as substantial remanent polarization. Such a substantial remanent polarization may allow for storing information as a function of a polarization state of a spontaneously polarizable layer or a spontaneously polarizable material.

In general, a remanent polarization (also referred to as retentivity or remanence) may be present in a material layer in the case that the material layer may remain polarized upon reduction of an applied electric field (E) to zero, therefore, a certain value for the electrical polarization (P) of the material layer may be detected. Illustratively, a polarization remaining in a material when the electric field is reduced to zero may be referred to as remanent polarization. Therefore, the remanence of a material may be a measure of the residual polarization in the material in the case that an applied electric field is removed. In general, ferroelectricity and anti-ferroelectricity may be concepts to describe a spontaneous polarization of a material similar to ferromagnetism and anti-ferromagnetism used to describe remanent magnetization in magnetic materials. According to various aspects, an electric coercive field, E_{C}, (also referred to as coercive field) may be or may represent the electric field required to depolarize a remanent-polarizable layer. In some aspects, the memory element may be remanent-polarizable, thereby providing the remanent polarization capability of the SPOC structure 110. In other aspects, the memory element may consist of a material that is spontaneously polarizable but shows no remanence (e.g., an anti-ferroelectric material) and additional conditions are implemented to generate an internal electric-field within the anti-ferroelectric material to thereby provide the remanent polarization capability of the SPOC structure 110. Hence, a non-remanent polarizable material, such as an anti-ferroelectric (“antiferroelectric”) material may exhibit remanent polarizable properties within certain structures. An internal electric-field within an anti-ferroelectric material may be caused (e.g., applied, generated, maintained, as examples) by various strategies: e.g., by implementing floating nodes that may be charged to voltages different from zero volts, and/or by implementing charge storage layers, and/or by using doped layers, and/or by using electrode layers that adapt electronic work-functions to generate an internal electric field, by using an encapsulation structure which introduces compressive stress or tensile stress onto the memory element, thereby establishing the spontaneously polarizable properties, only as examples.

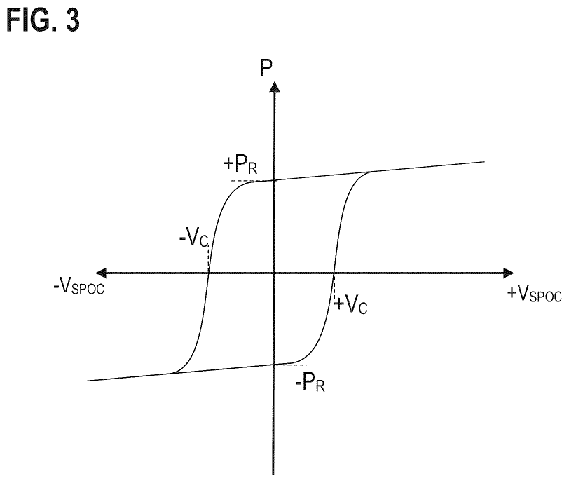

FIG. 3 shows a typical hysteresis curve (in some aspects referred to as polarization curve) of a remanent-polarizable memory cell, where the polarization, P, is plotted as a function of the voltage, V_{SPOC}, across the SPOC structure 110. The voltage, V_{SPOC}, across the SPOC structure 110 may be a voltage difference between a voltage applied at the first terminal 104 (i.e., the plateline voltage V_{PL}) and a voltage applied at the storage node 114 and. FIG. 3 shows the (capacitive) memory cell 102(m*, n*) exemplarily as a remanent-polarizable memory cell to illustrate various aspects thereof. The graph shows two remanent polarization states (+P_{R}, −P_{R}) of the memory element that may represent the programmable states of the memory element. For example, the memory cell 102(m*, n*) may be programmed to a (positive) remanent polarization state +P_{R} (representing, for example, a bit of digital information with a value of “0”) or to a (negative) remanent polarization state −P_{R} (representing, for example, a bit of digital information with a value of “1”), or vice versa, by applying a programming voltage across the SPOC structure 110 that is sufficient to program the corresponding remanent polarization state (e.g., via applying a plateline voltage V_{PL} and a bitline voltage V_{BL}). Therefore, the polarization curve of the remanent-polarizable memory cell may also be referred to as memory window. The (positive) remanent polarization state +P_{R} may be associated with a (negative) coercive voltage −V_{C} (representing a corresponding (negative) electric field) and the (negative) remanent polarization state −P_{R} may be associated with a (positive) coercive voltage +V_{C} (representing a corresponding (positive) electric field). The coercive voltage ±V_{C} may represent the voltage to depolarize the memory cell from its remanent polarization state ∓P_{R} (viz. to bring the polarization P to zero).

The polarization curve shown in FIG. 3 may be an initial (e.g., predefined, non-imprinted) polarization curve. In this (non-imprinted) condition, both remanent polarization state ±P_{R} may be substantially equally stable (|+P_{R}|=|−P_{R}|; (|+V_{C}|=−V_{C}|;), and there may be no polarization state favored over the other. The polarization (viz. hysteresis) curve may thus be centered (with respect to the origin of both V_{SPOC} and P).

To read the stored memory state of the SPOC structure 110, a read voltage is typically applied across the SPOC structure 110 that is sufficient to program a remanent state of the state-programmable memory element to a predefined state. This develops a charge, Q_{SPOC}, that depends on the programmed state before the read voltage was applied, where if the read-out operation caused the state-programmable memory element to switch to a new state (e.g., the predefined state is different from the previously programmed state), a larger charge (resulting from a dielectric charge of the memory element and a switching charge (also referred to as polarization charge) due to switching the memory (polarization) state) will be provided, whereas if the read operation caused the state-programmable memory element to be re-programmed to the same state (e.g., the predefined state is the same as the previously programmed state), little charge (resulting from a dielectric charge of the memory element) will be provided from the memory element. Hence, in order to program a remanent (polarization) state ∓P_{R}, an absolute value of the read voltage, V_{read}, has to be greater than the corresponding coercive voltage ±V_{C} by a (e.g., predefined) threshold voltage value. For example, the absolute value of the read voltage, V_{read}, may be greater than the corresponding coercive voltage ±V_{C} by at least 0.5 V.

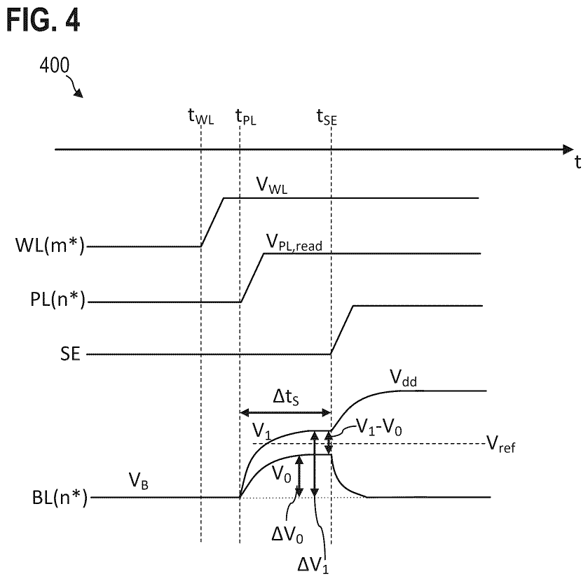

In the following, an exemplary read-out operation for reading the memory state of the memory cell 102(m*, n*) is detailed with reference to FIG. 2 and FIG. 4 which shows a typical timing diagram 400 of a read-out operation.

During a read-out operation, the corresponding bitline BL(n*) may be first discharged to the base voltage, V_{B}, (e.g., ground, GND). Then, a wordline voltage, V_{WL}, may be applied (at a wordline charging time step t_{WL}) to the corresponding wordline WL(m*) to activate (e.g., open) the access device (such as the FET structure 112). Once, a plateline voltage, V_{PL}, (e.g., a read plateline voltage, V_{PL, read}) is applied (at a plateline charging time step t_{PL}) to the corresponding plateline PL(n*), the charge (Q_{SPOC}) is provided to corresponding BL(n*) that depends on the (programmed) memory state of the SPOC structure 110 and its dielectric capacitance. Due to this, a characteristic voltage is developed onto the corresponding BL(n*). With reference to FIG. 4, a first voltage V₁ may develop onto the corresponding BL(n*) in the case that the memory cell 102(m*, n*) stores a logic “1” (also referred to as “1” bit) as memory state and a second voltage V₀ may develop onto the corresponding BL(n*) in the case that the memory cell 102(m*, n*) stores a logic “0” (also referred to as “0” bit) as memory state. The time until fully charging the corresponding BL(n*) may be referred to as signal development time, Δtₛ. The difference between the first voltage V₁ and the second voltage V₀ may define the read window (V₁−V₀).

With reference to FIG. 2, the controller 200 may be configured to apply, during the read-out operation, the plateline voltage, V_{PL}, and the wordline voltage, V_{WL}. The corresponding bitline BL(n*) may be connected to a sensing circuit 300. According to various aspects, the memory cells that share a common bitline BL(n) may be connected to a same sensing circuit 300. Thus, the memory cell arrangement 100 may include one or more sensing circuits 300. In some aspects, the controller 200 may include the one or more sensing circuits. In the read-out operation, the sensing circuit 300 may be configured to sense the voltage developed at the bitline (i.e., the bitline voltage V_{BL}) and compare the sensed voltage with a predefined reference voltage, Vref (see, for example, FIG. 4). Thus, if the developed bitline voltage, V_{BL}, is greater than the predefined reference voltage, V_{ref}, (in the case of V₁) the memory state is determined as a “1” and if the developed bitline voltage, V_{BL}, is less than the predefined reference voltage, V_{ref}, (in the case of V₀) the memory state is determined as “0”. Therefore, the reference voltage, V_{ref}, may also be referred to as threshold voltage. The sensing circuit 300 may, for example, be or include a sense amplifier. The sense amplifier may discharge the corresponding bitline BL(n*) to the base voltage, V_{B}, in the case that the memory state is a logic “0” and may charge the corresponding bitline BL(n*) to the (positive) supply voltage, V_{dd}, in the case that the memory state is a logic “1”. To write the memory cell 102(m*, n*) into a logic “1” (as memory state), the (positive) supply voltage, V_{dd}, may be applied at the corresponding bitline BL(n*) and about 0 V may be applied at the corresponding plateline PL(n*). To write the memory cell 102(m*, n*) into a logic “0” (as memory state), the (positive) supply voltage, V_{dd}, may be applied at the corresponding plateline PL(n*) and about 0 V may be applied at the corresponding bitline BL(n*). As understood, a single sense amplifier may be connected to multiple memory cells that are part of a same group and therefore share a common bitline BL(n*).

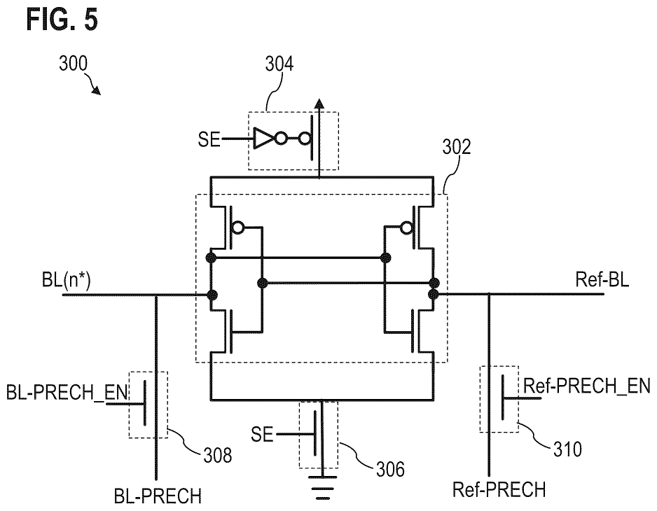

FIG. 5 shows an exemplary configuration of a sense amplifier 300 according to various aspects. The sense amplifier 300 may be differential or dual-sided, where one side of the sense amplifier 300 is connected to one bitline (such as the corresponding bitline BL(n*) of one array of memory cells and the other side of the sense amplifier 300 is connected to another bitline (such as a reference bitline, Ref-BL) of a different array of memory cells. In a dual-sided configuration, one side of the sense amplifier 300 may be actively operated to read a bitline (such as the corresponding bitline BL(n*) in the present example) of one set of cells while the other side (its complement) of the sense amplifier acts as a reference (such as the reference bitline, Ref-BL, in the present example), and vice versa. In a dual-sided sense amplifier configuration, each sense amplifier may be understood as a latch 302 whose two inputs are the two bitlines, where the latch is enabled by a sense enable (SE) signal (e.g., provided at a sense enable time step t_{SE}). The latch 302 may be connected via one or more sense enable transistors/switches 304, 306 that, when enabled, connects one side (the corresponding bitline BL(n*) in the present example) of its supply to a supply power and the other side (the reference bitline, Ref-BL, in the present example) of its supply to the base voltage (e.g., ground). The enable transistors/switches 304, 306 may be operated by the sense enable (SE) signal to supply power to the latch 302 when the SE signal is enabled and to leave the supply floating when the SE signal is not enabled. The side of the latch 302 may be selected by pre-charging transistors/switches 308, 310 which may be operated by corresponding (enable) signals (BL-PRECH_EN, Ref-PRECH_EN) that, when enabled, connect the corresponding bitline to its corresponding source voltage (BL-PRECH, REF-PRECH) for charging/discharging the corresponding bitline.

As detailed herein, in a memory cell arrangement, such as the memory cell arrangement 100, a plurality of memory cells may be coupled to a common plateline and a common bitline. Hence, other memory cells 102(m=1 to M/m*, n*) may also be connected to the corresponding plateline PL(n*) and to the corresponding bitline BL(n*) of the memory cell 102(m*, n*). Although those other memory cells 102(m=1 to M/m*, n*) may not be selected (i.e., no wordline voltage V_{WL} may be applied at their corresponding wordlines to open their FET structures 112; it is understood that an inhibit voltage may be applied to those other wordlines), there may be a coupling between those other memory cells 102(m=1 to M/m*, n*) and the corresponding bitline BL(n*) of the selected memory cell 102(m*, n*).

FIG. 6 shows various aspects of electrical polarization and imprint characteristics of a remanent-polarizable memory cell according to various aspects. In FIG. 6, the initial (viz. non-shifted, non-imprinted, centered) polarization curve (as shown in FIG. 3) is shown by dotted lines.

As detailed herein, the imprint effect may (energetically) stabilize the remanent memory state the remanent-polarizable memory cell is in over time. Illustratively, the imprint effect may shift the memory window (and thus the coercive voltages +¿V_{C} and −¿V_{C}) stabilizing an actual (viz. current) memory state. Thus, in the case that the memory cell 102(m*, n*) is in the negative remanent polarization state −P_{R} (representing, for example, logic “1”), this negative remanent polarization state −P_{R} may become more stable over time due to the imprint effect, as illustrated by a shift of the polarization curve (viz. memory window) in direction of +¿V_{SPOC}, as shown in diagram 602. Accordingly, in the case that the memory cell 102(m*, n*) is in the positive remanent polarization state +P_{R} (representing, for example, logic “0”), this positive remanent polarization state +P_{R} may become more stable over time due to the imprint effect, as illustrated by a shift of the polarization curve (viz. memory window) in direction of −¿V_{SPOC}, as shown in diagram 604. As illustratively shown, with increasing shift (viz. increasing time) the remanence of the opposite polarization state (viz. the polarization state opposite to the stabilized polarization state) is reduced. The shift of the memory window may be associated with a (coercive) shift, ΔV_{C}, of the coercive field. The coercive voltages +¿V_{C} and −¿V_{C} of the imprinted memory window may also be referred to as imprinted coercive voltages +¿V_{C, imprint} and −¿V_{C, imprint}. The (coercive) shift, ΔV_{C}, may be substantially the same for both coercive voltages +¿V_{C} and −¿V_{C}. Hence, the imprint effect may not change a width of the memory window.

To write the memory cell 120(m*, n*) again into the imprinted memory state, the write voltage, V_{write}, may be increased to be greater than the coercive voltage ±V_{C} by the (e.g., predefined) threshold voltage value. This may be referred to as same-state retention. However, there may be a threshold shift (and viz. a threshold time period) after which the memory cell 120(m*, n*) cannot be written into the opposite memory state (viz. the logic “1” in the case that the imprinted memory state is the logic “0” and vice versa). Writing the opposite memory state may be referred to as opposite-state retention. With reference to diagram 602, after the threshold time period, the polarization curve may shift such that also the (negative) coercive voltage −¿V_{C} has a positive voltage value of V_{SPOC}, not allowing to switch to the other memory state (since the opposite memory state may not be stable).

According to various aspects, the imprint related effects may be temperature dependent. Illustratively, the time it takes a remanent polarizable layer to reach an imprinted condition may decrease for increasing temperature (e.g. for an increasing temperature of the memory cell or of the environment surrounding the memory cell, for example a temperature the memory cell reaches during operation). As an example, at room temperature (e.g. 25° C.) a memory cell may become an imprinted memory cell after more than one day, for example more than one week. As another example, at a temperature of about 85° C. a memory cell may become an imprinted memory cell after a few hours, for example after 2 hours, for example after 5 hours. As a yet further example, at a temperature of about 300° C. a memory cell may become an imprinted memory cell after a few minutes, for example after 10 min, for example after 30 min, or after 1 hour.

In the following, various aspects are detailed that allow to address this imprint effect to prohibit that the opposite state cannot be written any more.

For this, the controller 200 (e.g., a state machine and/or a memory controller) may be configured to cause a conditioning operation and/or an inversion operation. Both may lead to a de-imprinting of the memory cell 102(m*, n*). In the following, for illustration and conciseness, various aspects of the conditioning operation and the inversion operation are detailed with reference to the memory cell 102(m*, n*). It is understood that each of the conditioning operation and the inversion operation may be applied to more than one memory cell of the plurality of memory cells 102(m=1 to M, n=1 to N) at substantially a same time (e.g., in a same cycle).

As detailed herein, there may be a threshold shift associated with a threshold time duration (in some aspects referred to as threshold time period) after which the memory cell 120(m*, n*) cannot be written into the opposite memory state (viz. the logic “1” in the case that the imprinted memory state is the logic “0” and vice versa). The time period for which the memory cell 102(m*, n*) is in the same memory state may be referred to as storage period. Hence the storage period may be, for example, a period of time during which a memory state a memory cell is residing in is not switched (e.g., a period between two write operations). The memory characteristics may be still valid for the specific memory state that has become favored; however, a switch of the memory state and a subsequent readout may be prone to errors.

However, it has been found that even in the case that a memory cell was not written for the threshold time duration and, hence, cannot be written into the memory state opposite to the imprinted memory state, the imprinted memory state can still be read (out) when using a read voltage, V_{read}, greater than the imprinted coercive voltage ±V_{C, imprint} of the imprinted memory state.

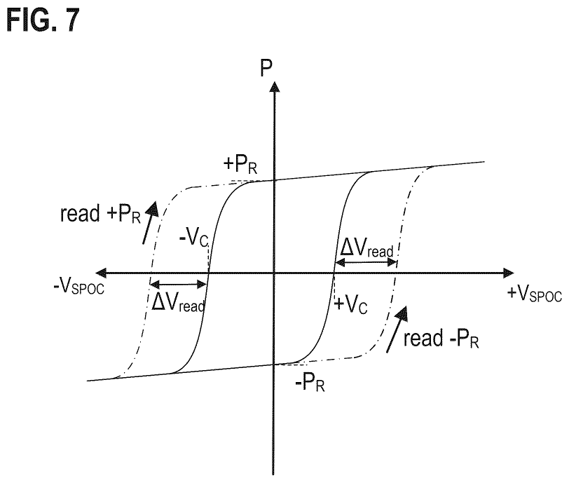

According to various aspects, with reference to FIG. 7, increasing the absolute value of the read voltage, V_{read}, by a (e.g., predefined) voltage difference, ΔV_{read}, may allow to (e.g., destructively) read the memory state of the remanent-polarizable memory cell 102(m*, n*) even in the case of imprinting. Illustratively, the (e.g., predefined) voltage difference, ΔV_{read}, may defined an offset voltage the memory window can be shifted but its memory state still be read out.

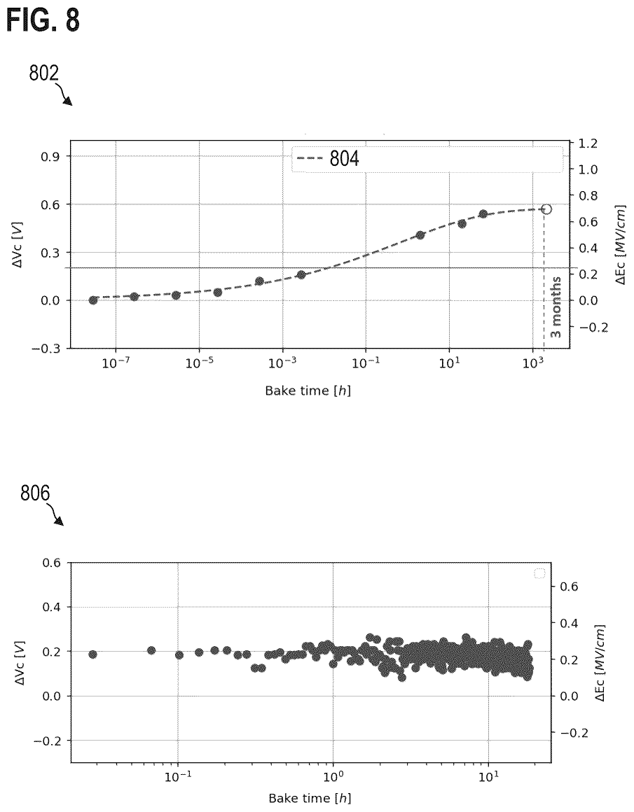

Diagram 802 in FIG. 8 shows a temporal behavior of the imprint. The imprint is given as the coercive shift, ΔV_{C}, resulting from the imprint effect and the time is given by a bake time at 85° C. As shown, after about three months, the coercive shift, ΔV_{C}, is about 0.6V (resulting from curve 804 extrapolated to the empty circle at three months; with full circles being measurements).

The conditioning operation may include that a first subset of memory cells of the plurality of memory cells 102(m=1 to M, n=1 to N) is selected. The first subset of memory cells may include one or more memory cells of the plurality of memory cells 102(m=1 to M, n=1 to N). The conditioning operation may include that a second subset of memory cells of the plurality of memory cells 102(m=1 to M, n=1 to N) is selected. The first subset of memory cells and the second subset of memory cells may include a same number of memory cells. It is understood that one or more memory cells may be dedicated (viz. predefined) as second subset of memory cells. For example, the memory cell arrangement 100 may be designed with an overprovisioning, viz. having an overprovisioned memory area, and this (added) memory area may provide (e.g., may be used as) the second subset of memory cells.

In general memory devices, such as solid-state discs (SSD), may include a non-volatile flash memory for persistently storing data and a volatile dynamic random-access memory (DRAM) that provides a write cache (which may also be referred to as write buffer) for volatilely storing data that are to be written into the non-volatile flash memory for persistent storage. Using the DRAM write cache increases the speed of writing data to and/or reading data from the non-volatile flash memory, thereby mitigating the limitations of the non-volatile flash memory. According to various aspects, the memory cell arrangement 100 detailed herein may provide both, a portion for volatilely storing data and a portion for non-volatile storing data. Thus, plurality of memory cells 102(m=1 to M, n=1 to N) of the memory cell arrangement 100 may include a first set of memory cells that are dedicated to non-volatilely storing data a second set of memory cells (different from the first set of memory cells) dedicated to volatilely storing data. In this case, the second subset of memory cells may include memory cells of the second set of memory cells.

According to various aspects, all memory cells of the plurality of memory cells 102(m=1 to M, n=1 to N) except for the second subset of memory cells may be dedicated to non-volatilely storing data and the second subset of memory cells may be dedicated to be used for the conditioning operation.

According to various aspects, the first subset memory cells and the second subset of memory cells may each be a respective memory bank or a respective memory segment of the memory cell arrangement 100.

According to various aspects, all memory cells of the plurality of memory cells 102(m=1 to M, n=1 to N) may be dedicated to non-volatilely storing data and the controller 200 may ensure that, at any time, there is a free storage space that can serve as second set of memory cells. The free storage space may be associated with memory cells not non-volatilely storing data. Hence, the memory cells associated with the free storage space may be written without data loss. The conditioning operation may include determining the memory cells of the free storage space as the second subset of memory cells. In some aspects, there may be a predefined number of memory cells associated with the free storage space. In other aspects, the number of memory cells of the free storage space may be variable. In the latter case, the conditioning operation may include determining the first subset of memory cells based on a number of memory cells of the second subset of memory cells (such that the first subset and the second subset include a same number of memory cells). Each memory cell of the first subset of memory cell may be (e.g., bijectively) associated with a memory cell of the second subset of memory cells. Hence, for each memory cell of the first subset of memory cell there may be an (bijectively) assigned memory cell of the second subset of memory cells.

According to various aspects, the conditioning operation may include reading the respective memory state of each memory cell of the first subset of memory cells (e.g., concurrently (e.g., substantially simultaneously) or one after the other) and writing the assigned memory cell of the second subset of memory cells into the respective memory state. Illustratively, the data stored in the memory cells of the first subset of memory cells may be transferred to the second subset of memory cells. The reading of the respective memory state of each memory cell of the first subset of memory cells may include applying an imprint read voltage drop, V_{read, imprint}, over the respective memory state. This imprint read voltage drop, V_{read, imprint}, may be greater than the read voltage, V_{read}, by the (e.g., predefined) voltage difference, ΔV_{read} (viz. the V_{read, imprint}=V_{read}+ΔV_{read}; see, for example, FIG. 7). Hence, using this imprint read voltage drop, V_{read, imprint}, allows to read the memory state even in the case that the memory state would be imprinted. Hence, the absolute value of the imprint read voltage drop, V_{read, imprint}, may be greater than the absolute value of the read voltage, V_{read}, by the (e.g., predefined) voltage difference, ΔV_{read}. As an example, in the case that V_{read}=2.0V and ΔV_{read}=0.5V the value of the imprint read voltage drop, V_{read, imprint} may be 2.5V.

Subsequently, an imprint removal for removing a potential imprint may be carried out for each memory cell of the first subset of memory cells. This imprint removal for removing the potential imprint of a remanent-polarizable memory cell 102(m*, n*) may include an alternating sequence of voltage drops of opposite polarities over the SPOC structure 110 of the remanent-polarizable memory cell 102(m*, n*). The alternating sequence of voltage drops of opposite polarities may include alternatingly writing the memory cell 102(m*, n*) into the first memory state and the second memory state. It has been found that such an alternating sequence can remove the imprint of the memory cell 102(m*, n*). For example, the alternating sequence may include cycling 1 Gbit of data (e.g., in parallel) with (e.g., a single 1 kHz) alternatingly writing the first state and the second state.

It is understood that each cycle of the alternating sequence of voltage drops of opposite polarities includes a first voltage drop of first polarity and a second voltage drop of second polarity opposite to the first polarity.

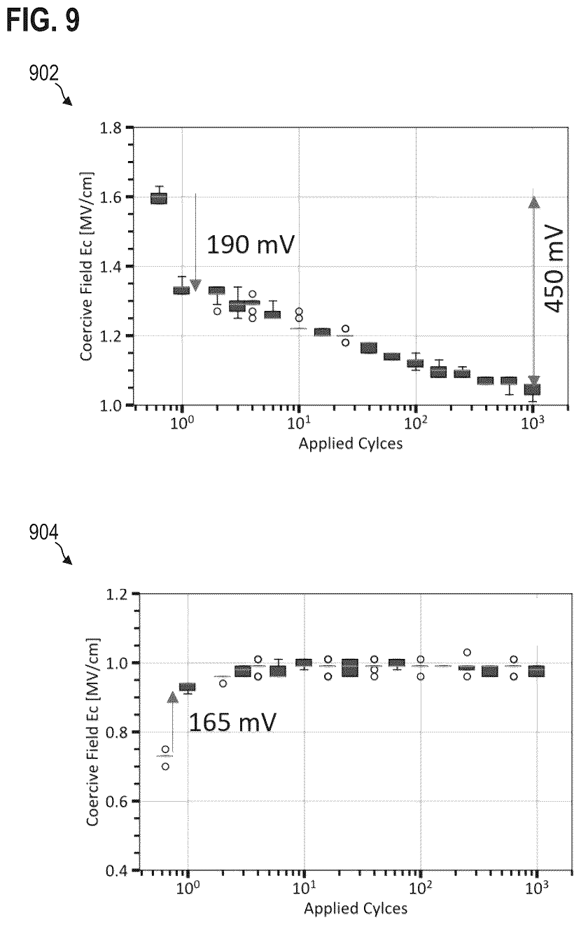

FIG. 9 shows various aspects of reducing the imprint by applying the alternating sequence of voltage drops of opposite polarities over the SPOC structure 110 (viz. the remanent-polarizable memory layer thereof).

Diagram 902 shows an imprinted negative remanent polarization state −P_{R} (representing, for example, logic “1”) having a (positive) coercive field, E_{C} (representing the coercive voltage +V_{C}) of about 1.6 V prior to applying the alternating sequence of voltage drops. As illustratively shown, already one cycle of the alternating sequence of voltage drops of opposite polarities (viz. one first voltage drop and one second voltage drop) reduces the coercive field, E_{C}, by about 190 mV. A number of about 1000 cycles completely removes the imprint.

Diagram 904 shows an imprinted positive remanent polarization state +P_{R} (representing, for example, logic “0”) having a (positive) coercive field, E_{C} (representing the coercive voltage +V_{C}) of about 0.75 V prior to applying the alternating sequence of voltage drops. As illustratively shown, already one cycle of the alternating sequence of voltage drops of opposite polarities (viz. one first voltage drop and one second voltage drop) increases the coercive field, E_{C}, by about 165 mV. Already 10 cycles completely remove the imprint.

To remove the imprint simultaneously without differentiating between which memory state is imprinted, according to various aspects, the alternating sequence of voltage drops may include about 1000 cycles or more.

According to various aspects, the conditioning operation may be applied to all memory cells of the plurality of memory cells 102(m=1 to M, n=1 to N) that are dedicated to non-volatilely storing data. For example, the conditioning operation may include that the data of all memory cells of the plurality of memory cells 102(m=1 to M, n=1 to N) that are dedicated to non-volatilely storing data are copied from one subset of memory cells to another subset of memory cells (viz. read from one subset of memory cells and written to another subset of memory cells) and the imprint of the subset of memory cells from which to data are copied to the other subset of memory cells is then removed using the imprint removal described herein.

In some aspects, after the imprint removal (viz. the alternating sequence of voltage drops of opposite polarities) is applied to the first subset of memory cells, the data stored in a next subset of memory cells (e.g., having a same number of memory cells as the first subset of memory cells) may be read and written to the first subset of memory cells and, subsequently, the imprint removal may be applied to this next subset of memory cells. This may be carried out until the imprint removal is applied to all memory cells that are dedicated to non-volatilely storing data.

In other aspects, the after the imprint removal (viz. the alternating sequence of voltage drops of opposite polarities) is applied to the first subset of memory cells, the data stored in the second subset of memory cells are copied back to the first subset of memory cells and, subsequently, the data stored in the next subset of memory cells may be read and written to the second subset of memory cells prior to applying the imprint removal to this next subset of memory cells.

For example, each subset of memory cells may be one or more than one memory bank or one or more than one segment of the memory cell arrangement 100. Hence, the imprint removal may be carried out bank-wise or segment-wise. Applying the conditioning operation segment-wise requires more time than applying the conditioning operation bank-wise, but the storage size dedicated to the conditioning operation (e.g., as second subset of memory cells) is less (e.g., only about 4 Mbit compared to 256 Mbit of a memory bank). According to various aspects, the controller 200 may be configured to cause the conditioning operation based on a user setting that specifies the size of the second subset of memory cells (e.g., whether the conditioning operation is to be applied bank-wise or segment-wise). This allows the user to select between a larger usable storage area (due to reduce storage size of the second subset of memory cells when using the segment-wise approach) and a faster startup when using the bank-wise approach.

As an example, each subset of memory cells may be two memory banks coupled to a same sensing circuit 300. The imprint removal may be applied to both memory banks in parallel.

As an example, applying the alternating sequence of voltage drops may take about 10 ms and a total duration of the imprint removal may in this case take about 80 ms. To apply the conditioning operation bank-wise on all memory cells of the memory cell arrangement 100, a time of about 160 ms per memory bank that stored data non-volatilely.

As detailed herein, the memory cell arrangement 100 may allow to memories for volatile data storage, such as DRAM and/or serial NAND (sNAND). In those cases using a volatile data storage in combination with a non-volatile data storage, when powering up the storage device, non-volatile data have to be transferred from the non-volatile data storage to the volatile data storage. The time duration required for this data transfer is significantly greater than the time duration required for applying the conditioning operation on all memory cells of the memory cell arrangement 100.

According to various aspects, the data may be stored in the memory cell arrangement 100 using an error correction code (ECC). This may reduce (e.g., prevent) the risk of data loss when transferring the data between the subsets of memory cells as part of the conditioning operation. Further, this may avoid error accumulation resulting from the copying during the conditioning operation

According to various aspects, the controller 200 may be configured to cause the conditioning operation every time when powering up (viz. start running) the memory cell arrangement 100. Additionally or alternatively, the controller 200 may be configured to receive timing information indicating for each memory cell 102(m*, n*) a respective time duration since the memory state of the memory cell 102(m*, n*) was last written. For example, during operation the memory cell arrangement 100 may store the timing information (e.g., determined using a clock signal). According to various aspects, the controller 200 may be configured to cause the conditioning operation every time when powering up the memory cell arrangement 100 since there may be no (timing) information on how long the memory cell arrangement 100 was switched off. Optionally (e.g., when not using the inversion operation detailed herein or in addition to the inversion operation), the controller 200 may be configured to cause the condition operation during operation of the memory cell arrangement 100 in the case that a memory cell 102(m*, n*) was not written for the threshold time duration. For example, this (predefined) threshold time duration may be about three months.

To ensure that the data can be written save from the first subset of memory cells to the second subset of memory cells, the controller 200 may be configured to cause the imprint removal (for removing a potential imprint) for each memory cell of the second subset of memory cells prior to writing the data from the first subset of memory cells thereto.

According to various aspects, the controller 200 may be configured to cause the imprint removal (for removing a potential imprint) for each memory cell of the second subset of memory cells when powering down the memory cell arrangement 100 and/or when powering up the memory cell arrangement 100 (prior to writing the data from the first subset of memory cells to the second subset of memory cells). The controller 200 may cause the conditioning operation when powering up the memory cell arrangement 100. As part of the conditioning operation, the data from the first subset of memory cells are transferred to the second subset of memory cells from whose memory cells the potential imprint is already removed. After the removal of the potential imprint of the first subset of memory cells, the data from the next subset of memory cells are transferred to the first subset of memory cells and the potential imprint of this next subset of memory cells is removed, and so on. This may be carried out until the potential imprint of all memory cells of the memory cell arrangement 100 is removed.

According to various aspects, an operating system (OS) of the memory cell arrangement 100 may be run (e.g., started, booted) only after the potential imprint of all memory cells of the memory cell arrangement 100 is removed. Since the conditioning operation is independent of the running of the OS, the conditioning operation allows to restore data even after time periods longer than the threshold time duration (of e.g., about 3 months). Illustratively, the conditioning operation detailed herein can prohibit data loss.

For illustration, an exemplary implementation of imprint removal (using the alternating sequence of voltage drops of opposite polarity) when powering up the memory cell arrangement 100 may be as follows: Apply the wordline voltage V_{WL} at a selected wordline (with the first subset of memory cells including the memory cells coupled to the selected wordline); and in each cycle of a plurality of cycles: apply the write voltage, V_{write}, at all bitlines and apply 0 V at all platelines (e.g., to write all memory cells of the first subset of memory cells to a logic “1”); wait for a predefined time period; apply the write voltage, V_{write}, at all platelines and apply 0 V at all bitlines (e.g., to write all memory cells of the first subset of memory cells to a logic “0”); wait for the predefined time period (go to next cycle until the potential imprint is removed from all memory cells dedicated to non-volatile data storage).

Additionally or alternatively to the conditioning operation, the inversion operation may be carried out (during operation of the memory cell arrangement 100). For example, the conditioning operation may be carried out when powering up the memory cell arrangement 100 (and/or during operation of the memory cell arrangement 100 in the case that a memory cell was not written for the threshold time duration) and the inversion operation may be carried out during operation (viz. during power on) of the memory cell arrangement 100. As detailed herein, the inversion operation allows to prevent the memory cells from imprinting (viz. to prevent the coercive voltage V_{C} from shifting).

The inversion operation may be carried out by a state-machine or a memory controller of the controller 200. According to various aspects, at least part of the conditioning operation may be carried out by a memory controller of the controller 200 using corresponding software that manages the data transfer during the conditioning operation.

The controller 200 may be configured to cause the inversion operation cyclically. Hence the inversion operation may be carried out in each cycle of a plurality of cycles.

When, in the following, referring to the inversion operation, it is understood that it is referred to a respective cycle thereof. Each cycle of the inversion operation may have a predefined length (e.g., a length in a range from about 60 seconds to about 140 seconds (e.g., in a range from about 80 seconds to about 120 seconds, such as about 100 seconds)). A cycle length may also be referred to as cycle duration.

The inversion operation may be applied cyclically to all memory cells of the memory cell arrangement 100.

In the following, various aspects of the inversion operation with reference to at least one memory cell 102(m*, n*). It is understood that this serves for illustration and conciseness and that the at least one memory cell 102(m*, n*) described may be one or more than one memory cell to which the inversion operation is applied.

In general, the inversion operation may include to read the memory state of the at least one memory cell 102(m*, n*), to invert the read memory state into an inverted memory state, and to write the at least one memory cell 102(m*, n*) into the inverted memory state.

As detailed herein, the remanent polarization state may indicate the memory state. Thus, in the case that the remanent polarization state is the positive remanent polarization state +P_{R} (representing, for example, logic “0”), the inverted memory state is the negative remanent polarization state −P_{R} (representing, for example, logic “1”), and vice versa.

In a consecutive cycle, the memory state is inverted again. Thus, after every even cycle, the inverted memory state corresponds to the memory state that is initially be written, and after every uneven cycle, the inverted memory state is the opposite memory state of the one that is initially be written.

The inversion operation may further include that inversion information are stored which indicate whether an actual (viz. current) memory state of the at least one memory cell 102(m*, n*) corresponds to an intended memory state that was written in a write operation different from writing the inverted memory state or corresponds to an inverted version of the intended memory state. Hence, the inversion information may, for example, indicate whether an even or uneven number of cycles of the inversion operation is applied to the at least one memory cell 102(m*, n*). It is understood that this serves for illustration and that the inversion information may include any kind of information indicating the initially written memory state

As detailed herein, the memory cell may imprint to the written memory state over time, thereby stabilizing the written memory state. Thus, when switching the memory state in regular cycles, the memory cell imprints in opposite direction, thereby compensating the imprint resulting from the previous cycles. Illustratively, the inversion operation allows to prevent the memory cell from imprinting over time, whereas the conditioning operation allows to (comparatively fast) remove imprint in the case that the memory cell is imprinted to a memory state.

Diagram 806 in FIG. 8 shows the coercive shift, ΔV_{C}, resulting from the imprint effect when applying the inversion operation cyclically every 100 seconds(s). As illustratively shown, the coercive shift, ΔV_{C}, is substantially stable over time. Illustratively, this allows to compensate the imprint effect during operation of the memory cell arrangement 100.

According to various aspects, a wordline WL(m*) of the plurality of wordlines may be selected and the inversion operation may be applied to each memory cell 102(m*, n=1 to N) coupled to this selected wordline WL(m*). In this case, the inversion information may, for example, include an inversion bit for the selected wordline indicating whether the memory cells coupled to the selected wordline are in an inverted version of the initially written memory state or not.

The inversion of the read memory state into the inverted memory state may be carried out by the sensing circuit 300 or another sensing circuit. The sensing circuit 300 may include an inverter configured to invert the memory state into the inverted memory state. The sensing circuit 300 may be a primary sense amplifier. According to various aspects, the memory cell arrangement 100 may include one or more secondary sense amplifiers. In some aspects, the primary sense amplifier 300 may be configured to transfer data indicating the memory state of the at least one memory cell 102(m*, n*) to the secondary sense amplifier, the secondary sense amplifier may then invert the memory state into the inverted memory state. Adding an inverter to the primary sense amplifier 300 increases complexity and cost. Using, on the other hand, the secondary sense amplifier for inverting the memory state allows to omit this inverter and, thus, requires less memory array footprint, but the inversion of the memory state may take more time.

As an example for using the secondary sense amplifier for inverting the memory state: a plurality of primary sense amplifiers 300 may transfer data indicating a respective memory state for each memory cell of a set of memory cells (e.g., including blocks of 64 bits). The secondary sense amplifier may invert each memory state to the inverted memory state and may provide data indicating the inverted memory states back to the plurality of primary sense amplifiers 300. As an example, the controller 200 (e.g., a state machine thereof) may provide the following sequence of commands: An ACT command causing a row (viz. memory cells connected to a same wordline) to open and read the respective memory state of all memory cells connected to this same wordline using the respective primary sense amplifier 300; a READ command causing a transfer to data (e.g., 64 bits) from the primary sense amplifiers 300 to the secondary sense amplifier; an INVERT command to invert the memory states; a WRITE command to write the inverted memory states; and a PRECHARGE command to close the row (viz. the wordline). This may be carried out until all memory cells of the memory cell arrangement 100 are inverted and then a next cycle thereof may start.

Alternatively to writing the inverted memory state according to the inversion operation, the memory cell may be written into the same, read memory state again. It has been found that writing the same memory state again may reduce the imprint slightly. However, in comparison to the inversion operation, writing the same memory state again does not allow to prevent imprint but only slows down the shift of the coercive voltage. This re-writing of the same memory state may be similar to a refresh cycle used for DRAM and/or sNAND.

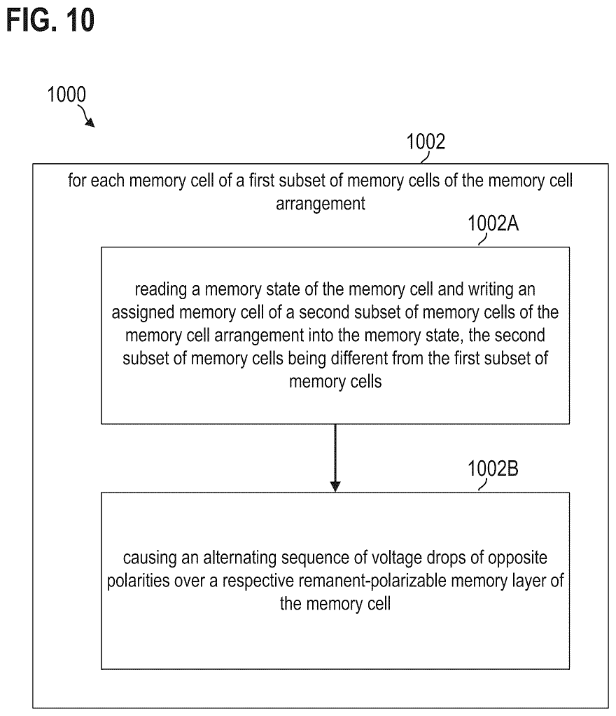

FIG. 10 shows a flow diagram of a method 1000 for operating a memory cell arrangement (e.g., the memory arrangement 100) when powering up the memory cell arrangement according to various aspects.

The method 1000 may include (in 1002) for each memory cell of a first subset of memory cells of the memory cell arrangement: reading (in 1002A) a memory state of the memory cell and writing an (e.g., bijectively) assigned memory cell of a second subset of memory cells of the memory cell arrangement into the (read) memory state, the second subset of memory cells being different from the first subset of memory cells.

The method 1000 may include (in 1002) for each memory cell of the first subset of memory cells: causing (in 1002B) an alternating sequence of voltage drops of opposite polarities over a respective remanent-polarizable memory layer of the memory cell.

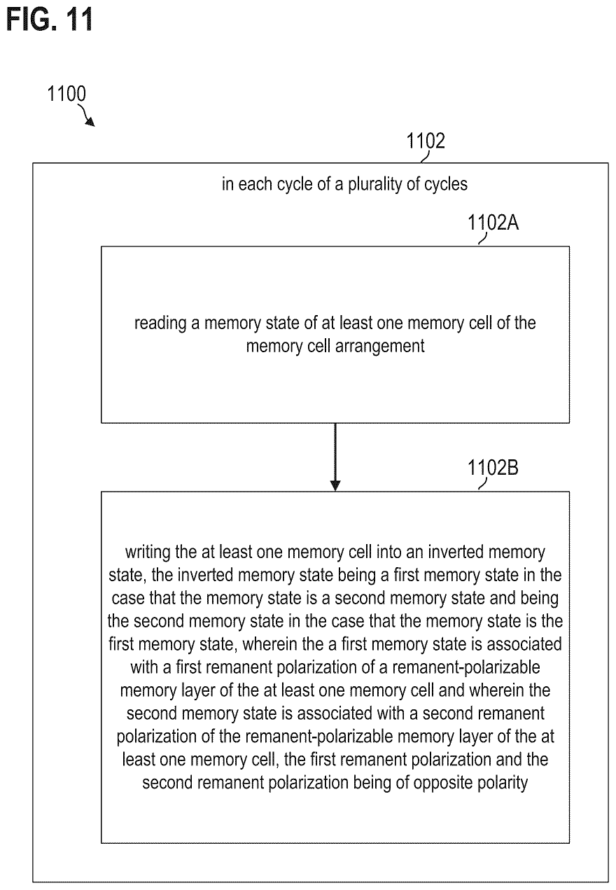

FIG. 11 shows a flow diagram of a method 1100 for operating a memory cell arrangement (e.g., the memory arrangement 100) according to various aspects.

The method 1100 may include (in 1102) in each cycle of a plurality of cycles: reading (in 1102A) a (respective) memory state of at least one memory cell of the memory cell arrangement.

The method 1100 may include (in 1102) in each cycle of the plurality of cycles: writing (in 1102B) the at least one memory cell into an inverted memory state, the inverted memory state being a first memory state in the case that the (read) memory state is a second memory state and being the second memory state in the case that the (read) memory state is the first memory state. The first memory state may be associated with a first remanent polarization of a remanent-polarizable memory layer of the at least one memory cell and the second memory state may be associated with a second remanent polarization of the remanent-polarizable memory layer of the at least one memory cell. The first remanent polarization and the second remanent polarization may be of opposite polarity.

It may be intended that aspects described in relation to one or more of the methods may apply also to the memory cell arrangement, and vice versa. For example, a method may include an execution of one or more functions a component of the memory cell arrangement (e.g., the one or more write modification circuits) is configured to.

In the following, various examples are provided that may include one or more aspects described above with reference to the memory cell 102, the memory cell arrangement 100, and to the methods described herein. It may be intended that aspects described in relation to one or more of the methods may apply also to the memory cell and/or the memory cell arrangement, and vice versa.

Example 1 is a memory cell arrangement including: a plurality of memory cells, wherein each memory cell of the plurality of memory cells includes a respective remanent-polarizable memory layer; and a controller (e.g., a state machine and/or a memory controller) configured to cause a conditioning (e.g., de-imprinting) operation (e.g., when powering up the memory cell arrangement) for each memory cell of a first subset of memory cells of the plurality of memory cells, the conditioning operation including for a respective memory cell of the first subset of memory cells: reading a memory state of the respective memory cell and writing an (e.g., bijectively) assigned memory cell of a second subset of memory cells of the plurality of memory cells into the (read) memory state, the second subset of memory cells being different from the first subset of memory cells; and, subsequently, causing an alternating sequence of voltage drops of opposite polarities over the respective remanent-polarizable memory layer of the respective memory cell.

In Example 2, the subject matter of Example 1 can optionally include that each memory cell of the plurality of memory cells is writable into (at least) a first memory state associated with a first remanent polarization of the respective remanent-polarizable memory layer and a second memory state associated with a second remanent polarization of the respective remanent-polarizable memory layer, the first remanent polarization and the second remanent polarization being of opposite polarity; and wherein causing the alternating sequence of voltage drops of opposite polarities over the respective remanent-polarizable memory layer of the respective memory cell includes writing the respective memory cell alternatingly into the first memory state and the second memory state.

In Example 3, the subject matter of Example 1 or 2 can optionally include that the alternating sequence of voltage drops is further configured to shift an imprinted memory window of the respective remanent-polarizable memory element of the respective memory cell into a direction associated with a non-imprinted memory window.

In Example 4, the subject matter of any one of Examples 1 to 3 can optionally include that reading the memory state of the respective memory cell includes applying a first voltage drop over the respective remanent-polarizable memory element, the first voltage drop having a first voltage value; and wherein, after the conditioning operation, the controller is configured to read the memory state of the respective memory cell applying a second voltage drop over the respective remanent-polarizable memory element of the respective memory cell, the second voltage drop having a second voltage value less than the first voltage value.

In Example 5, the subject matter of any one of Examples 1 to 4 can optionally include that the controller is configured to cause the conditioning operation when powering up the memory cell arrangement.

In Example 6, the subject matter of Example 5 can optionally include that the controller is configured to cause the conditioning operation when powering up the memory cell arrangement prior to running (e.g., booting) an operating system of the memory cell arrangement.

In Example 7, the subject matter of Example 6 can optionally include that, when powering up the memory cell arrangement, the controller is configured to cause the conditioning operation successively for a plurality of subsets of memory cells of the plurality of memory cells until the conditioning operation is applied to all memory cells of the plurality of memory cells prior to running the operating system of the memory cell arrangement.

In Example 8, the subject matter of any one of Examples 5 to 7 can optionally include that the controller is configured to cause a further conditioning operation for each memory cell of the second subset of memory cells when powering down the memory cell arrangement, the further conditioning operation including for a respective memory cell of the second subset of memory cells: causing an (e.g., the) alternating sequence of voltage drops of opposite polarities over the respective remanent-polarizable memory layer of the respective memory cell prior to powering down the memory cell arrangement.

In Example 9, the subject matter of any one of Examples 1 to 8 can optionally include that the controller is configured to cause a (e.g., the) further conditioning operation for each memory cell of the second subset of memory cells prior to writing the assigned memory cell of the second subset of memory cells into the respective memory state, the further conditioning operation including for a respective memory cell of the second subset of memory cells: causing an (e.g., the) alternating sequence of voltage drops of opposite polarities over the respective remanent-polarizable memory layer of the respective memory cell.

In Example 10, the subject matter of any one of Examples 1 to 9 can optionally include that the first subset of memory cells is dedicated to non-volatilely storing data and wherein the second subset of memory cells is dedicated to volatilely storing data.

In Example 11, the subject matter of any one of Examples 1 to 10 can optionally include that the memory cell arrangement is configured to store data in the plurality of memory cells using an error correction code (ECC).

In Example 12, the subject matter of any one of Examples 1 to 11 can optionally include that the controller is configured to: receive timing information indicating, for each memory cell of the first subset of memory cells, a respective time duration since the respective memory state of the memory cell was last written; and cause the conditioning operation in the case that the respective time duration of at least one memory cell of the first subset of memory cells is greater (e.g., longer) than a predefined threshold time duration (e.g., about three months).

In Example 13, the subject matter of any one of Examples 1 to 12 can optionally include that the first subset and the second subset of memory cells are each associated with a respective memory bank or a respective memory segment of the memory cell arrangement.

In Example 14, the subject matter of any one of Examples 1 to 13 can optionally include that the conditioning operation further includes after causing the alternating sequence of voltage drops of opposite polarities over the respective remanent-polarizable memory layer of the respective memory cell: reading a respective memory state of each memory cell of the second subset of memory cells or of a third subset (different from the first subset) of memory cells of the plurality of memory cells and writing an (e.g., the in the case of the second subset) assigned memory cell of the first subset of memory cells into the (read) respective memory state.

In Example 15, the subject matter of any one of Examples 1 to 13 can optionally include that the conditioning operation further includes for the respective memory cell of the first subset of memory cells after causing the alternating sequence of voltage drops of opposite polarities over the respective remanent-polarizable memory layer: reading a memory state of the assigned memory cell and writing the respective memory cell of the first subset of memory cells into the (read) memory state.

In Example 16, the subject matter of any one of Examples 1 to 13 can optionally include that the conditioning operation further includes for the respective memory cell of the first subset of memory cells after causing the alternating sequence of voltage drops of opposite polarities over the respective remanent-polarizable memory layer: reading a memory state of a (assigned) memory cell of a third subset of memory cells of the plurality of memory cells, the third subset of memory cells being different from the first subset of memory cells; and writing the respective memory cell of the first subset of memory cells into the (read) memory state.

In Example 17, the subject matter of Example 16 can optionally include that the conditioning operation further includes for the respective memory cell of the first subset of memory cells after writing the respective memory cell of the first subset of memory cells into the (read) memory state: causing an alternating sequence of voltage drops of opposite polarities over the respective remanent-polarizable memory layer of the memory cell of the third subset of memory cells.

In Example 18, the subject matter of any one of Examples 1 to 17 can optionally include that the controller is configured to determine the second subset of memory cells as a set of memory cells of the plurality of memory cells that can be written without data loss (e.g., as free space), and to determine the first subset of memory cells based on a number of memory cells of the second subset of memory cells.

In Example 19, the subject matter of any one of Examples 1 to 18 can optionally include that each memory cell of the plurality of memory cells is writable into (at least) a first memory state associated with a first remanent polarization of the respective remanent-polarizable memory layer and a second memory state associated with a second remanent polarization of the respective remanent-polarizable memory layer, the first remanent polarization and the second remanent polarization being of opposite polarity; and wherein the controller is further configured to cyclically (viz. in a plurality of consecutive cycles) cause an inversion operation, each cycle of the inversion operation including: reading a (respective) memory state of at least one memory cell of the plurality of memory cells; writing the at least one memory cell into an inverted memory state, the inverted memory state being the first memory state in the case that the (read) memory state is the second memory state and being the second memory state in the case that the (read) memory state is the first memory state.

In Example 20, the subject matter of Example 19 can optionally include that the inversion operation is carried out cyclically for each memory cell of the plurality of memory cells.

In Example 21, the subject matter of Example 19 or 20 can optionally include that the inversion operation is carried out cyclically in (regular) cycles of predefined length.

In Example 22, the subject matter of Example 21 can optionally include that the predefined length is in a range from about 60 seconds to about 140 seconds (e.g., in a range from about 80 seconds to about 120 seconds, such as about 100 seconds).

In Example 23, the subject matter of any one of Examples 19 to 22 can optionally include that reading the memory state of the at least one memory cell includes: a first (e.g., primary) sense amplifier sensing a characteristic voltage at a control line the at least one memory cell is coupled to, the characteristic voltage representing the memory state of the at least one memory cell, and determining the memory state of the at least one memory cell based on the characteristic voltage; and wherein each cycle of the inversion operation further includes: transferring data indicating the memory state of the at least one memory to a second (e.g., secondary) sense amplifier (different from the first sense amplifier), and the second sense amplifier inverting the memory state to the inverted memory state.

In Example 24, the subject matter of any one of Examples 19 to 22 can optionally include that reading the memory state of the at least one memory cell includes: a (e.g., primary) sense amplifier sensing a characteristic voltage at a control line the at least one memory cell is coupled to, the characteristic voltage representing the memory state of the at least one memory cell, and determining the memory state of the at least one memory cell based on the characteristic voltage; and wherein the sense amplifier includes an inverter configured to invert the (determined) memory state into the inverted memory state.

In Example 25, the memory cell arrangement of any one of Examples 19 to 24 can optionally further include: a plurality of bitlines, a plurality of platelines, and a plurality of wordlines for selectively addressing one or more memory cells of the plurality of memory cells; wherein each cycle of the inversion operation includes: selecting a wordline of the plurality of wordlines; for each memory cell of the plurality of memory cells (e.g., including the at least one memory cell) that are coupled to the (selected) wordline: reading a memory state of the memory cell; and writing the memory cell into the inverted memory state.

In Example 26, the subject matter of Examples 21 and 25 can optionally include that the controller is configured to cyclically cause a walking wordline operation, a respective cycle of the walking wordline operation including: for each memory cell of the plurality of memory cells that is coupled to a selected wordline: reading a memory state of the memory cell and writing a memory cell that is coupled to a wordline prior to the selected wordline according to a predefined order into the memory state; and selecting a wordline posterior to the selected wordline according to the predefined order as selected wordline of a consecutive cycle.

In Example 27, the subject matter of any one of Examples 19 to 26 can optionally include that each cycle of the inversion operation includes: storing (e.g., in one or more further memory cells) information indicating whether an actual (viz. current) memory state of the at least one memory cell corresponds to an intended memory state that was written in a write operation different from writing the inverted memory state or corresponds to an inverted version of the intended memory state.

Example 28 is a memory cell arrangement including: a plurality of memory cells, wherein each memory cell of the plurality of memory cells includes a respective remanent-polarizable memory layer and is writable into (at least) a first memory state associated with a first remanent polarization of the respective remanent-polarizable memory layer and a second memory state associated with a second remanent polarization of the respective remanent-polarizable memory layer, the first remanent polarization and the second remanent polarization being of opposite polarity; and a controller (e.g., a state machine and/or a memory controller) configured to cyclically (viz. in a plurality of consecutive cycles) cause an inversion operation, each cycle of the inversion operation including: reading a (respective) memory state of at least one memory cell of the plurality of memory cells; writing the at least one memory cell into an inverted memory state, the inverted memory state being the first memory state in the case that the (read) memory state is the second memory state and being the second memory state in the case that the (read) memory state is the first memory state.

In Example 29, the subject matter of Example 28 can optionally include that the inversion operation is carried out cyclically for each memory cell of the plurality of memory cells.

In Example 30, the subject matter of Example 28 or 29 can optionally include that the inversion operation is carried out cyclically in (regular) cycles of predefined length.

In Example 31, the subject matter of Example 30 can optionally include that the predefined length is in a range from about 60 seconds to about 140 seconds (e.g., in a range from about 80 seconds to about 120 seconds, such as about 100 seconds).

In Example 32, the subject matter of any one of Examples 28 to 31 can optionally include that reading the memory state of the at least one memory cell includes: a first (e.g., primary) sense amplifier sensing a characteristic voltage at a control line the at least one memory cell is coupled to, the characteristic voltage representing the memory state of the at least one memory cell, and determining the memory state of the at least one memory cell based on the characteristic voltage; and wherein each cycle of the inversion operation further includes: transferring data indicating the memory state of the at least one memory to a second (e.g., secondary) sense amplifier (different from the first sense amplifier), and the second sense amplifier inverting the memory state to the inverted memory state.

In Example 33, the subject matter of any one of Examples 28 to 32 can optionally include that reading the memory state of the at least one memory cell includes: a (e.g., primary) sense amplifier sensing a characteristic voltage at a control line the at least one memory cell is coupled to, the characteristic voltage representing the memory state of the at least one memory cell, and determining the memory state of the at least one memory cell based on the characteristic voltage; and wherein the sense amplifier includes an inverter configured to invert the (determined) memory state into the inverted memory state.

In Example 34, the memory cell arrangement of any one of Examples 28 to 33 can optionally further include: a plurality of bitlines, a plurality of platelines, and a plurality of wordlines for selectively addressing one or more memory cells of the plurality of memory cells; wherein each cycle of the inversion operation includes: selecting a wordline of the plurality of wordlines; for each memory cell of the plurality of memory cells (e.g., including the at least one memory cell) that are coupled to the (selected) wordline: reading a memory state of the memory cell; and writing the memory cell into the inverted memory state.

In Example 35, the subject matter of Examples 30 and 34 can optionally include that the controller is configured to cyclically cause a walking wordline operation, a respective cycle of the walking wordline operation including: for each memory cell of the plurality of memory cells that is coupled to a selected wordline: reading a memory state of the memory cell and writing a memory cell that is coupled to a wordline prior to the selected wordline according to a predefined order into the memory state; and selecting a wordline posterior to the selected wordline according to the predefined order as selected wordline of a consecutive cycle.

In Example 36, the subject matter of any one of Examples 28 to 35 can optionally include that each cycle of the inversion operation includes: storing (e.g., in one or more further memory cells) information indicating whether an actual (viz. current) memory state of the at least one memory cell corresponds to an intended memory state that was written in a write operation different from writing the inverted memory state or corresponds to an inverted version of the intended memory state.

In Example 37, the subject matter of any one of Examples 28 to 36 can optionally include that the controller is configured to cause a conditioning (e.g., de-imprinting) operation (e.g., when powering up the memory cell arrangement) for each memory cell of a first subset of memory cells of the plurality of memory cells, the conditioning operation including for a respective memory cell of the first subset of memory cells: reading a memory state of the respective memory cell and writing an (e.g., bijectively) assigned memory cell of a second subset of memory cells of the plurality of memory cells into the (read) memory state, the second subset of memory cells being different from the first subset of memory cells; and, subsequently, causing an alternating sequence of voltage drops of opposite polarities over the respective remanent-polarizable memory layer of the respective memory cell.

In Example 38, the subject matter of Example 37 can optionally include that causing the alternating sequence of voltage drops of opposite polarities over the respective remanent-polarizable memory layer of the respective memory cell includes writing the respective memory cell alternatingly into the first memory state and the second memory state.

In Example 39, the subject matter of Example 36 or 37 can optionally include that the alternating sequence of voltage drops is further configured to shift an imprinted memory window of the respective remanent-polarizable memory element of the respective memory cell into a direction associated with a non-imprinted memory window.

In Example 40, the subject matter of any one of Examples 36 to 38 can optionally include that reading the memory state of the respective memory cell includes applying a first voltage drop over the respective remanent-polarizable memory element, the first voltage drop having a first voltage value; and wherein, after the conditioning operation, the controller is configured to read the memory state of the respective memory cell applying a second voltage drop over the respective remanent-polarizable memory element of the respective memory cell, the second voltage drop having a second voltage value less than the first voltage value.

In Example 41, the subject matter of any one of Examples 36 to 40 can optionally include that the controller is configured to cause the conditioning operation when powering up the memory cell arrangement.

In Example 42, the subject matter of Example 41 can optionally include that the controller is configured to cause the conditioning operation when powering up the memory cell arrangement prior to running (e.g., booting) an operating system of the memory cell arrangement.

In Example 43, the subject matter of Example 42 can optionally include that, when powering up the memory cell arrangement, the controller is configured to cause the conditioning operation successively for a plurality of subsets of memory cells of the plurality of memory cells until the conditioning operation is applied to all memory cells of the plurality of memory cells prior to running the operating system of the memory cell arrangement.

In Example 44, the subject matter of any one of Examples 41 to 43 can optionally include that the controller is configured to cause a further conditioning operation for each memory cell of the second subset of memory cells when powering down the memory cell arrangement, the further conditioning operation including for a respective memory cell of the second subset of memory cells: causing an (e.g., the) alternating sequence of voltage drops of opposite polarities over the respective remanent-polarizable memory layer of the respective memory cell prior to powering down the memory cell arrangement.

In Example 45, the subject matter of any one of Examples 36 to 44 can optionally include that the controller is configured to cause a (e.g., the) further conditioning operation for each memory cell of the second subset of memory cells prior to writing the assigned memory cell of the second subset of memory cells into the respective memory state, the further conditioning operation including for a respective memory cell of the second subset of memory cells: causing an (e.g., the) alternating sequence of voltage drops of opposite polarities over the respective remanent-polarizable memory layer of the respective memory cell.

In Example 46, the subject matter of any one of Examples 36 to 45 can optionally include that the first subset of memory cells is dedicated to non-volatilely storing data and wherein the second subset of memory cells is dedicated to volatilely storing data.

In Example 47, the subject matter of any one of Examples 36 to 46 can optionally include that the memory cell arrangement is configured to store data in the plurality of memory cells using an error correction code (ECC).

In Example 48, the subject matter of any one of Examples 36 to 47 can optionally include that the controller is configured to: receive timing information indicating, for each memory cell of the first subset of memory cells, a respective time duration since the respective memory state of the memory cell was last written; and cause the conditioning operation in the case that the respective time duration of at least one memory cell of the first subset of memory cells is greater (e.g., longer) than a predefined threshold time duration (e.g., about three months).

In Example 49, the subject matter of any one of Examples 36 to 48 can optionally include that the first subset and the second subset of memory cells are each associated with a respective memory bank or a respective memory segment of the memory cell arrangement.

In Example 50, the subject matter of any one of Examples 36 to 49 can optionally include that the conditioning operation further includes after causing the alternating sequence of voltage drops of opposite polarities over the respective remanent-polarizable memory layer of the respective memory cell: reading a respective memory state of each memory cell of the second subset of memory cells or of a third subset (different from the first subset) of memory cells of the plurality of memory cells and writing an (e.g., the in the case of the second subset) assigned memory cell of the first subset of memory cells into the (read) respective memory state.

In Example 51, the subject matter of any one of Examples 36 to 49 can optionally include that the conditioning operation further includes for the respective memory cell of the first subset of memory cells after causing the alternating sequence of voltage drops of opposite polarities over the respective remanent-polarizable memory layer: reading a memory state of the assigned memory cell and writing the respective memory cell of the first subset of memory cells into the (read) memory state.

In Example 52, the subject matter of any one of Examples 36 to 51 can optionally include that the conditioning operation further includes for the respective memory cell of the first subset of memory cells after causing the alternating sequence of voltage drops of opposite polarities over the respective remanent-polarizable memory layer: reading a memory state of a (assigned) memory cell of a third subset of memory cells of the plurality of memory cells, the third subset of memory cells being different from the first subset of memory cells; and writing the respective memory cell of the first subset of memory cells into the (read) memory state.

In Example 53, the subject matter of Example 52 can optionally include that the conditioning operation further includes for the respective memory cell of the first subset of memory cells after writing the respective memory cell of the first subset of memory cells into the (read) memory state: causing an alternating sequence of voltage drops of opposite polarities over the respective remanent-polarizable memory layer of the memory cell of the third subset of memory cells.

In Example 54, the subject matter of any one of Examples 36 to 53 can optionally include that the controller is configured to determine the second subset of memory cells as a set of memory cells of the plurality of memory cells that can be written without data loss (e.g., as free space), and to determine the first subset of memory cells based on a number of memory cells of the second subset of memory cells.

Example 55 is a method for operating a memory cell arrangement when powering up the memory cell arrangement, wherein each memory cell of a plurality of memory cells of the memory cell arrangement includes a respective remanent-polarizable memory layer, the method including: for each memory cell of a first subset of memory cells of the memory cell arrangement: reading a memory state of the memory cell and writing an (e.g., bijectively) assigned memory cell of a second subset of memory cells of the memory cell arrangement into the (read) memory state, the second subset of memory cells being different from the first subset of memory cells; and, subsequently, causing an alternating sequence of voltage drops of opposite polarities over the respective remanent-polarizable memory layer of the memory cell.

In Example 56, the subject matter of Example 55 can optionally include that causing the alternating sequence of voltage drops of opposite polarities over the respective remanent-polarizable memory layer of the memory cell includes writing the memory cell alternatingly into a first memory state and a second memory state, wherein the first memory state is associated with a first remanent polarization of the respective remanent-polarizable memory layer and the second memory state is associated with a second remanent polarization of the respective remanent-polarizable memory layer, the first remanent polarization and the second remanent polarization being of opposite polarity.

In Example 57, the subject matter of Example 55 or 56 can optionally include that the alternating sequence of voltage drops shifts an imprinted memory window of the respective remanent-polarizable memory element of the memory cell into a direction associated with a non-imprinted memory window.

In Example 58, the subject matter of any one of Examples 55 to 57 can optionally include that reading the memory state of the memory cell includes applying a first voltage drop over the respective remanent-polarizable memory element, the first voltage drop having a first voltage value; and the method further including after causing the alternating sequence of voltage drops of opposite polarities over the respective remanent-polarizable memory layer of the memory cell: reading the memory state of the memory cell by applying a second voltage drop over the respective remanent-polarizable memory element of the memory cell, the second voltage drop having a second voltage value less than the first voltage value.

In Example 59, the subject matter of any one of Examples 55 to 58 can optionally include that the method is carried out when powering up the memory cell arrangement.

In Example 60, the subject matter of Example 59 can optionally include that the method is carried out when powering up the memory cell arrangement prior to running (e.g., booting) an operating system of the memory cell arrangement.

In Example 61, the subject matter of Example 60 can optionally include that, when powering up the memory cell arrangement prior to running the operating system of the memory cell arrangement, the method is carried out successively for a plurality of subsets of memory cells of the plurality of memory cells until being carried out for all memory cells of the plurality of memory cells.

In Example 62, the method of any one of Examples 59 to 61 can optionally further include: for each memory cell of the second subset of memory cells when powering down the memory cell arrangement: causing an (e.g., the) alternating sequence of voltage drops of opposite polarities over the respective remanent-polarizable memory layer of each memory cell prior to powering down the memory cell arrangement.

In Example 63, the method of any one of Examples 55 to 62 can optionally further include: for each memory cell of the second subset of memory cells prior to writing the assigned memory cell of the second subset of memory cells into the respective memory state: causing an (e.g., the) alternating sequence of voltage drops of opposite polarities over the respective remanent-polarizable memory layer of each memory cell of the second subset of memory cells.

In Example 64, the subject matter of any one of Examples 55 to 63 can optionally include that the first subset of memory cells is dedicated to non-volatilely storing data and wherein the second subset of memory cells is dedicated to volatilely storing data.

In Example 65, the subject matter of any one of Examples 55 to 10 can optionally include that the memory cell arrangement is configured to store data in the plurality of memory cells using an error correction code (ECC).

In Example 66, the method of any one of Examples 55 to 65 can optionally further include: prior to reading the memory state of the memory cell: receiving timing information indicating, for each memory cell of the first subset of memory cells, a respective time duration since the respective memory state of the memory cell was last written; and reading the memory state of the memory cell in the case that the respective time duration of at least one memory cell of the first subset of memory cells is greater (e.g., longer) than a predefined threshold time duration (e.g., about three months).

In Example 67, the subject matter of any one of Examples 55 to 66 can optionally include that the first subset and the second subset of memory cells are each associated with a respective memory bank or a respective memory segment of the memory cell arrangement.

In Example 68, the method of any one of Examples 55 to 67 can optionally further include: after causing the alternating sequence of voltage drops of opposite polarities over the respective remanent-polarizable memory layer of the memory cell: reading a respective memory state of each memory cell of the second subset of memory cells or of a third subset (different from the first subset) of memory cells of the plurality of memory cells and writing an (e.g., the in the case of the second subset) assigned memory cell of the first subset of memory cells into the (read) respective memory state.

In Example 69, the method of any one of Examples 55 to 67 can optionally further include: after causing the alternating sequence of voltage drops of opposite polarities over the respective remanent-polarizable memory layer of the memory cell: reading a memory state of the assigned memory cell and writing the respective memory cell of the first subset of memory cells into the (read) memory state.

In Example 70, the method of any one of Examples 55 to 67 can optionally further include: after causing the alternating sequence of voltage drops of opposite polarities over the respective remanent-polarizable memory layer of the memory cell: reading a memory state of a (assigned) memory cell of a third subset of memory cells of the plurality of memory cells, the third subset of memory cells being different from the first subset of memory cells; and writing the respective memory cell of the first subset of memory cells into the (read) memory state.

In Example 71, the method of Example 70 can optionally further include: after writing a respective memory cell of the first subset of memory cells into the (read) memory state: causing an alternating sequence of voltage drops of opposite polarities over the respective remanent-polarizable memory layer of the respective memory cell of the third subset of memory cells.

In Example 72, the method of any one of Examples 55 to 71 can optionally further include: determining the second subset of memory cells as a set of memory cells of the plurality of memory cells that can be written without data loss (e.g., as free space); and determining the first subset of memory cells based on a number of memory cells of the second subset of memory cells.

Example 73 is a method for operating a memory cell arrangement, wherein each memory cell of the memory cell arrangement includes a respective remanent-polarizable memory layer and is writable into (at least) a first memory state associated with a first remanent polarization of the respective remanent-polarizable memory layer and a second memory state associated with a second remanent polarization of the respective remanent-polarizable memory layer, the first remanent polarization and the second remanent polarization being of opposite polarity, the method including: in each cycle of a plurality of cycles: reading a (respective) memory state of at least one memory cell of the memory cell arrangement; writing the at least one memory cell into an inverted memory state, the inverted memory state being the first memory state in the case that the (read) memory state is the second memory state and being the second memory state in the case that the (read) memory state is the first memory state.

In Example 74, the subject matter of Example 73 can optionally include that each cycle of the plurality of cycles has a (same) predefined length.

In Example 75, the subject matter of Example 75 can optionally include that the predefined length is in a range from about 60 seconds to about 140 seconds (e.g., in a range from about 80 seconds to about 120 seconds, such as about 100 seconds).

In Example 76, the subject matter of any one of Examples 73 to 75 can optionally include that reading the memory state of the at least one memory cell includes: a first (e.g., primary) sense amplifier sensing a characteristic voltage at a control line the at least one memory cell is coupled to, the characteristic voltage representing the memory state of the at least one memory cell, and determining the memory state of the at least one memory cell based on the characteristic voltage; and wherein each cycle of the plurality of cycles further includes: transferring data indicating the memory state of the at least one memory to a second (e.g., secondary) sense amplifier (different from the first sense amplifier), and the second sense amplifier inverting the memory state to the inverted memory state.

In Example 77, the subject matter of any one of Examples 73 to 75 can optionally include that reading the memory state of the at least one memory cell includes: a (e.g., primary) sense amplifier sensing a characteristic voltage at a control line the at least one memory cell is coupled to, the characteristic voltage representing the memory state of the at least one memory cell, and determining the memory state of the at least one memory cell based on the characteristic voltage; and wherein the sense amplifier includes an inverter configured to invert the (determined) memory state into the inverted memory state.

In Example 78, the subject matter of any one of Examples 73 to 77 can optionally include that each cycle of the plurality of cycles includes: selecting a wordline of a plurality of wordlines; for each memory cell (e.g., including the at least one memory cell) that is coupled to the (selected) wordline: reading a memory state of the memory cell; and writing the memory cell into the inverted memory state.

In Example 79, the method of Example 78 can optionally further include: cyclically causing a walking wordline operation, a respective cycle of the walking wordline operation including: for each memory cell that is coupled to a selected wordline: reading a memory state of the memory cell and writing a memory cell that is coupled to a wordline prior to the selected wordline according to a predefined order into the memory state; and selecting a wordline posterior to the selected wordline according to the predefined order as selected wordline of a consecutive cycle.

In Example 80, the subject matter of any one of Examples 73 to 79 can optionally include that each cycle of the plurality of cycles includes: storing (e.g., in one or more further memory cells) information indicating whether an actual (viz. current) memory state of the at least one memory cell corresponds to an intended memory state that was written in a write operation different from writing the inverted memory state or corresponds to an inverted version of the intended memory state.

The term “connected” may be used herein with respect to nodes, terminals, integrated circuit elements, and the like, to mean electrically connected, which may include a direct connection or an indirect connection, wherein an indirect connection may only include additional structures in the current path that do not influence the substantial functioning of the described circuit or device. The term “electrically conductively connected” that is used herein to describe an electrical connection between one or more terminals, nodes, regions, contacts, etc., may be understood as an electrically conductive connection with, for example, ohmic behavior, e.g., provided by a metal or degenerate semiconductor in absence of p-n junctions in the current path. The term “electrically conductively connected” may be also referred to as “galvanically connected”.

The term “coupled to” used herein with reference to functional parts of a memory cell (e.g., functional parts of a memory structure) that are coupled to respective nodes (e.g., plateline node, bitline node, and/or wordline node) of the memory cell may be understood as follows: the respective functional parts are electrically conductively connected to corresponding nodes and/or the respective functional parts itself provide the corresponding nodes. As an example, a source/drain node of a field-effect transistor memory structure may be electrically conductively connected to the source-line node of the memory cell or the source/drain node of the field-effect transistor memory structure may provide the source-line node of the memory cell. As another example, a source/drain node of the field-effect transistor memory structure may be electrically conductively connected to the bitline node of the memory cell or the source/drain node of the field-effect transistor memory structure may provide the bitline node of the memory cell.

The term “voltage” may be used herein with respect to “one or more bitline voltages”, “one or more wordline voltages”, “one or more plateline voltages”, “one or more sourceline voltages”, “one or more control line voltages”, “one or more base voltages” and the like. As an example, the term “base voltage” may be used herein to denote a reference voltage and/or a reference potential for the circuit. With respect to an electrical circuit, the base voltage may be also referred to as ground voltage, ground potential, virtual ground voltage, or zero volts (0 V). The base voltage of an electrical circuit may be defined by the power supply used to operate the electronic circuit. In the figures, the base voltage is exemplarily indicated using the ground symbol (also referred to as earth symbol). As another example, the term “control line voltage” may be used herein to denote a voltage that is provided to a control line, e.g., of a memory cell arrangement (for example a “wordline voltage” may be provided to a “wordline”, a “bitline voltage” may be provided to a bitline, and a “sourceline voltage” may be provided to a sourceline). The sign of a voltage difference (e.g., a voltage drop) may be defined as a potential inside a memory cell (e.g., at a first electrode portion) minus a potential at a second electrode portion of the memory cell.

Illustratively, a voltage provided to a node or a terminal may assume any suitable value depending on the intended operation of the circuit including the node or terminal. For example, a bitline voltage (referred to as V_{BL} or VBL) may be varied depending on the intended operation of the memory cell arrangement. Analogously, a wordline voltage (referred to as V_{WL} or VWL), a plateline voltage (referred to as V_{PL} or VPL), and/or plateline voltage (referred to as V_{PL} or VPL) may be varied depending on the intended operation of a memory cell arrangement. A voltage provided to a node or terminal may be defined by the respective potential applied to that node or terminal relative to the base voltage (referred to as V_{B}) of the circuit. Further, a voltage drop associated with two distinct nodes or terminals of a circuit may be defined by the respective voltages/potentials applied at the two nodes or terminals. As an example, a bitline voltage drop associated with a memory cell of a memory cell arrangement (e.g., an electrode of the memory cell) may be defined by the respective voltages/potentials applied at the corresponding memory cell (e.g., the electrode of the memory cell). A voltage drop over (short: a voltage over) over a component may also be referred to as a “voltage across” the component. Thus, a “voltage across” a component may be used herein to denote a voltage drop from a node on one side of a component (e.g. one side of a capacitor) to a node on the other side of the component (e.g., the other side of the capacitor).

The term “region” used with regards to a “source region”, “drain region”, “channel region”, and the like, may be used herein to mean a continuous region of a semiconductor portion (e.g., of a semiconductor wafer or a part of a semiconductor wafer, a semiconductor layer, a fin, a semiconductor nanosheet, a semiconductor nanowire, etc.,). In some aspects, the continuous region of a semiconductor portion may be provided by semiconductor material having only one dominant doping type.

In some aspects, two voltages may be compared with one another by relative terms such as “greater”, “higher”, “lower”, “less”, or “equal”, for example. It is understood that, in some aspects, a comparison may include the sign (positive or negative) of the voltage value or, in other aspects, the absolute voltage values (also referred to as the magnitude, or as the amplitude, e.g., of a voltage pulse) are considered for the comparison.

The terms “charging” or “discharging” an element having a capacitance associated therewith (such as a control line, a terminal, a capacitor (e.g., a capacitive memory element), etc., in an electronic circuit) may be used herein with respect to increase (in case of charging) or decrease (in case of discharging) the amount of electric charge stored in the element, for example. The electric charge stored in the element (based on the capacitance associated therewith) may be changed via a charging current or discharging current accordingly. In the case that an element having a capacitance associated therewith has an amount of electric charge stored therein, a corresponding voltage may be associated therewith as well. The relationship between a voltage of an element having a capacitance associated therewith (e.g., of a capacitor or an element having an inherent capacitance) and the electric charge stored therein may be determined based on commonly used equations considering the capacitance as a ratio of a change in electric charge to a corresponding change in the electric potential. The terms “charging” or “discharging” with reference to an element having a capacitance associated therewith may be used herein with respect to a technical current direction. The term “charge” or “charging” with reference to an element having a capacitance associated therewith, such as a control line, may be used herein to mean an increase of a voltage value being present (e.g., measurable) at the element, e.g., at the control line. The increase of the voltage value may be understood as a more positive voltage value: For example, an element having a capacitance associated therewith may be charged from a voltage value of −8V to a voltage value of −4V, from a voltage value of −2V to a voltage value of 2V, or from a voltage value of 3V to a voltage value of 6V (only as numerical examples). The term “discharge” or “discharging” with reference to an element having a capacitance associated therewith, such as a control line, may be used herein to mean a decrease of a voltage value being present (e.g., measurable) at the element, e.g., at the control line. The decrease of the voltage value may mean a more negative voltage value: For example, an element having a capacitance associated therewith may be discharged from a voltage value of 8V to a voltage value of 4V, from a voltage value of 2V to a voltage value of −2V, or from a voltage value of −3V to a voltage value of −6V (only as numerical examples).

The phrase “a current between” a first terminal or node and a second terminal or node may be used herein to mean a current from the first terminal or node to the second terminal or node as well as a current from the second terminal or node to the first terminal or node.

The phrase “a current through” a terminal, node, or region may be used herein to mean a current from the terminal or node to another terminal, another node, or another region as well as a current to the terminal, node, or region (e.g., from another terminal, another node, or another region).

A current may be detected using a current sense amplifier that outputs a voltage proportional to the current.

The terms “electrically conducting” or “electrically conductive” may be used herein interchangeably to describe a material or a layer having an electrical conductivity or an average electrical conductivity greater than 10⁶ S/m at a temperature of 20° C. The term “electrically insulating” may be used herein interchangeably to describe a material or a layer having an electrical conductivity or an average electrical conductivity less than 10⁻¹⁰ S/m at a temperature of 20° C. In some aspects, a difference in electrical conductivity between an electrically conducting material (or layer) and an electrically insulating material (or layer) may have an absolute value of at least 10¹⁰ S/m at a temperature of 20° C., or of at least 10¹⁵ S/m at a temperature of 20° C.

It may be understood, that the physical term “electrical conductivity” (also referred to as specific conductance, specific electrical conductance, as examples) may be defined as a material dependent property reciprocal to the physical term “electrical resistivity” (also referred to as specific electrical resistance, volume resistivity, as examples). Further properties of a layer or structure may be defined material dependent and the geometry dependent, e.g., by the physical terms “electrical resistance” and “electrical conductance”.

The terms “at least one” and “one or more” may be understood to include any integer number greater than or equal to one, i.e. one, two, three, four, [ . . . ], etc. The term “a plurality” or “a multiplicity” may be understood to include any integer number greater than or equal to two, i.e. two, three, four, five, [ . . . ], etc. The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of listed elements.

The phrase that an element or a group of elements “includes” another element or another group of elements may be used herein to mean that the other element or other group of elements may be part of the element or the group of elements or that the element or the group of elements may be configured or formed as the other element or the other group of elements (e.g., the element may be the other element).

The phrase “unambiguously assigned” may be used herein to mean a one-to-one-assignment (e.g., allocation, e.g., correspondence) or a bijective assignment. As an example, a first element being unambiguously assigned to a second element may include that the second element is unambiguously assigned to the first element. As another example, a first group of elements being unambiguously assigned to a second group of element may include that each element of the first group of elements is unambiguously assigned to a corresponding element of the second group of elements and that that corresponding element of the second group of elements is unambiguously assigned to the element of the first group of elements.

The verb “switch” may be used herein to describe a modification of the memory state a memory cell is residing in. For example, in the case that a memory cell is residing in a first memory state (e.g., the positive polarization state), the memory state the memory cell is residing in may be switched such that, after the switch, the memory cell may reside in a second memory state (e.g., the negative polarization state), different from the first memory state. The term “switch” may thus be used herein to describe a modification of the memory state a memory cell is residing in, from a first memory state to a second memory state.

The term “shift” may be used herein to describe a change of a property of a memory cell, such as a coercive voltage, a memory window, a polarization, and the like. For example, a coercive voltage (associated with a coercive field) of a memory cell may be shifted, such that after the shift a value of the coercive voltage may be higher or lower than the value of the coercive voltage before the shift.

It is noted that one or more functions described herein with reference to a memory cell, a memory cell arrangement, etc., may be accordingly part of a method, e.g., part of a method for operating a memory cell arrangement. Vice versa, one or more functions described herein with reference to a method, e.g., with reference to a method for operating a memory cell arrangement, may be implemented accordingly in a device or in a part of a device, for example, in a memory cell, a memory cell arrangement, etc.

While the invention has been particularly shown and described with reference to specific aspects, it should be understood by those skilled in the art that various changes in form and detail may be made therein without departing from the spirit and scope of the invention as defined by the appended claims. The scope of the invention is thus indicated by the appended claims and all changes, which come within the meaning and range of equivalency of the claims, are therefore intended to be embraced.

What is claimed is:

1. A memory cell arrangement, comprising:
a plurality of memory cells, wherein each memory cell of the plurality of memory cells comprises a respective remanent-polarizable memory layer; and
a controller configured to cause a conditioning operation for each memory cell of a first subset of memory cells of the plurality of memory cells, the conditioning operation comprising for a respective memory cell of the first subset of memory cells:
reading a memory state of the respective memory cell and writing an assigned memory cell of a second subset of memory cells of the plurality of memory cells into the memory state, the second subset of memory cells being different from the first subset of memory cells; and, subsequently,
causing an alternating sequence of voltage drops of opposite polarities over the respective remanent-polarizable memory layer of the respective memory cell.

2. The memory cell arrangement according to claim 1,
wherein each memory cell of the plurality of memory cells is writable into a first memory state associated with a first remanent polarization of the respective remanent-polarizable memory layer and a second memory state associated with a second remanent polarization of the respective remanent-polarizable memory layer, the first remanent polarization and the second remanent polarization being of opposite polarity; and
wherein causing the alternating sequence of voltage drops of opposite polarities over the respective remanent-polarizable memory layer of the respective memory cell comprises writing the respective memory cell alternatingly into the first memory state and the second memory state.

3. The memory cell arrangement according to claim 1,
wherein reading the memory state of the respective memory cell comprises applying a first voltage drop over the respective remanent-polarizable memory element, the first voltage drop having a first voltage value; and
wherein, after the conditioning operation, the controller is configured to read the memory state of the respective memory cell applying a second voltage drop over the respective remanent-polarizable memory element of the respective memory cell, the second voltage drop having a second voltage value less than the first voltage value.

4. The memory cell arrangement according to claim 1,
wherein the controller is configured to cause the conditioning operation when powering up the memory cell arrangement.

5. The memory cell arrangement according to claim 4,
wherein the controller is configured to cause the conditioning operation when powering up the memory cell arrangement prior to running an operating system of the memory cell arrangement.

6. The memory cell arrangement according to claim 5,
wherein, when powering up the memory cell arrangement, the controller is configured to cause the conditioning operation successively for a plurality of subsets of memory cells of the plurality of memory cells until the conditioning operation is applied to all memory cells of the plurality of memory cells prior to running the operating system of the memory cell arrangement.

7. The memory cell arrangement according to claim 1,
wherein the controller is configured to cause a further conditioning operation for each memory cell of the second subset of memory cells when powering down the memory cell arrangement, the further conditioning operation comprising for a respective memory cell of the second subset of memory cells:
causing an alternating sequence of voltage drops of opposite polarities over the respective remanent-polarizable memory layer of the respective memory cell prior to powering down the memory cell arrangement.

8. The memory cell arrangement according to claim 1,
wherein the controller is configured to cause a further conditioning operation for each memory cell of the second subset of memory cells prior to writing the assigned memory cell of the second subset of memory cells into the respective memory state, the further conditioning operation comprising for a respective memory cell of the second subset of memory cells:
causing an alternating sequence of voltage drops of opposite polarities over the respective remanent-polarizable memory layer of the respective memory cell.

9. The memory cell arrangement according to claim 1,
wherein the first subset of memory cells is dedicated to non-volatilely storing data and wherein the second subset of memory cells is dedicated to volatilely storing data.

10. The memory cell arrangement according to claim 1,
wherein the memory cell arrangement is configured to store data in the plurality of memory cells using an error correction code.

11. The memory cell arrangement according to claim 1,
wherein the controller is configured to:
receive timing information indicating, for each memory cell of the first subset of memory cells, a respective time duration since the respective memory state of the memory cell was last written; and
cause the conditioning operation in the case that the respective time duration of at least one memory cell of the first subset of memory cells is greater than a predefined threshold time duration.

12. The memory cell arrangement according to claim 1,
wherein the first subset and the second subset of memory cells are each associated with a respective memory bank or a respective memory segment of the memory cell arrangement.

13. The memory cell arrangement according to claim 1,
wherein the conditioning operation further comprises for the respective memory cell of the first subset of memory cells after causing the alternating sequence of voltage drops of opposite polarities over the respective remanent-polarizable memory layer:
reading a memory state of the assigned memory cell and writing the respective memory cell of the first subset of memory cells into the memory state; or
reading a memory state of a memory cell of a third subset of memory cells of the plurality of memory cells, the third subset of memory cells being different from the first subset of memory cells, and writing the respective memory cell of the first subset of memory cells into the memory state.

14. The memory cell arrangement according to claim 1,
wherein the controller is configured to determine the second subset of memory cells as a set of memory cells of the plurality of memory cells that can be written without data loss, and to determine the first subset of memory cells based on a number of memory cells of the second subset of memory cells.

15. A memory cell arrangement, comprising:
a plurality of memory cells, wherein each memory cell of the plurality of memory cells comprises a respective remanent-polarizable memory layer and is writable into a first memory state associated with a first remanent polarization of the respective remanent-polarizable memory layer and a second memory state associated with a second remanent polarization of the respective remanent-polarizable memory layer, the first remanent polarization and the second remanent polarization being of opposite polarity; and
a controller configured to cyclically cause an inversion operation, each cycle of the inversion operation comprising:
reading a memory state of at least one memory cell of the plurality of memory cells;
writing the at least one memory cell into an inverted memory state, the inverted memory state being the first memory state in the case that the memory state is the second memory state and being the second memory state in the case that the memory state is the first memory state.

16. The memory cell arrangement according to claim 15,
wherein the inversion operation is carried out cyclically in cycles of predefined length, wherein the predefined length is in a range from about 60 seconds to about 140 seconds.

17. The memory cell arrangement according to claim 15,
wherein reading the memory state of the at least one memory cell comprises:
a first sense amplifier sensing a characteristic voltage at a control line the at least one memory cell is coupled to, the characteristic voltage representing the memory state of the at least one memory cell, and
determining the memory state of the at least one memory cell based on the characteristic voltage; and
wherein each cycle of the inversion operation further comprises:
transferring data indicating the memory state of the at least one memory to a second sense amplifier, and
the second sense amplifier inverting the memory state to the inverted memory state.

18. The memory cell arrangement according to claim 15, further comprising:
a plurality of bitlines, a plurality of platelines, and a plurality of wordlines for selectively addressing one or more memory cells of the plurality of memory cells;
wherein each cycle of the inversion operation comprises:
selecting a wordline of the plurality of wordlines;
for each memory cell of the plurality of memory cells that are coupled to the wordline:
reading a memory state of the memory cell; and
writing the memory cell into the inverted memory state.

19. The memory cell arrangement according to claim 15,
wherein each cycle of the inversion operation comprises:
storing information indicating whether an actual memory state of the at least one memory cell corresponds to an intended memory state that was written in a write operation different from writing the inverted memory state or corresponds to an inverted version of the intended memory state.

20. A method for operating a memory cell arrangement when powering up the memory
cell arrangement, wherein each memory cell of the memory cell arrangement comprises a respective remanent-polarizable memory layer, the method comprising:
for each memory cell of a first subset of memory cells of the memory cell arrangement:
reading a memory state of the memory cell and writing an assigned memory cell of a second subset of memory cells of the memory cell arrangement into the memory state, the second subset of memory cells being different from the first subset of memory cells; and, subsequently,
causing an alternating sequence of voltage drops of opposite polarities over the respective remanent-polarizable memory layer of the memory cell.
